(19) United States
(12) Patent Application Publication
(10) Pub. No.: US 2026/0107644 A1
(43) Pub. Date: Apr. 16, 2026

(54) DISPLAY APPARATUS, METHOD OF MANUFACTURING THE SAME, AND ELECTRONIC APPARATUS

(71) Applicant: SAMSUNG DISPLAY CO., LTD., Yongin-si (KR)

(72) Inventors: Kyongjun Kim, Yongin-si (KR); Sangseop Kum, Yongin-si (KR); Keunsoo Lee, Yongin-si (KR); Wooho Jeong, Yongin-si (KR); Kyungchan Chae, Yongin-si, Gyeonggi-do (KR)

(21) Appl. No.: 19/226,343

(22) Filed: Jun. 3, 2025

(30) Foreign Application Priority Data
Oct. 15, 2024 (KR) 10-2024-0140544

(51) Int. Cl. H10K 59/124; H10K 59/121

(52) U.S. Cl. CPC H10K 59/124; H10K 59/1213

(57) ABSTRACT

A display apparatus includes a substrate. A first semiconductor layer is arranged over the substrate. A first gate layer is arranged over the first semiconductor layer. A second gate layer is arranged over the first gate layer. A first interlayer insulating layer is arranged over the second gate layer. The first interlayer insulating layer includes a groove pattern having a downwardly concave shape. A second semiconductor layer is arranged over the first interlayer insulating layer. The second semiconductor layer includes an oxide semiconductor. A third gate layer is arranged over the second semiconductor layer. A first conductive layer is arranged over the third gate layer. The first conductive layer is electrically connected to the second gate layer. The second semiconductor layer is arranged in the groove pattern.

### CROSS-REFERENCE TO RELATED APPLICATION

This application claims priority under 35 U.S.C. § 119 to Korean Patent Application No. 10-2024-0140544, filed on Oct. 15, 2024 in the Korean Intellectual Property Office, the present disclosure of which is incorporated by reference in its entirety herein.

### 1. Technical Field

One or more embodiments relate to a display apparatus, a method of manufacturing the display apparatus, and an electronic apparatus, and more particularly, to a display apparatus including a thin film transistor with increased electrical characteristics, a method of manufacturing the display apparatus, and an electronic apparatus.

### 2. Discussion of Related Art

Display apparatuses may display images in response to receiving electronic signals concerning the images. Display apparatuses may be used as display units that are applied to a variety of electronic products, including small electronic products, such as mobile phones, or large electronic products, such as televisions.

A display apparatus may include a plurality of pixels that receive an electrical signal to emit light to display an image to the outside (e.g., the external environment). Each pixel may include a light emitting device, which may be, for example, an organic light emitting diode (OLED) in the case of an organic light emitting display apparatus. Generally, in an organic light emitting display apparatus, thin film transistors and organic light emitting diodes are formed over a substrate and the organic light emitting diodes emit light and operate by themselves.

An electronic apparatus may provide a visual interface necessary for a user through a display apparatus.

### SUMMARY

One or more embodiments include a display apparatus including a thin film transistor with increased electrical characteristics, a method of manufacturing the display apparatus, and an electronic apparatus. However, these problems are merely examples and the scope of the present disclosure is not limited thereto.

Additional aspects will be set forth in part in the description which follows and, in part, will be apparent from the description, or may be learned by practice of the presented embodiments of the present disclosure.

According to an embodiment of the present disclosure, a display apparatus includes a substrate. A first semiconductor layer is arranged over the substrate. A first gate layer is arranged over the first semiconductor layer. A second gate layer is arranged over the first gate layer. A first interlayer insulating layer is arranged over the second gate layer. The first interlayer insulating layer includes a groove pattern having a downwardly concave shape. A second semiconductor layer is arranged over the first interlayer insulating layer. The second semiconductor layer includes an oxide semiconductor. A third gate layer is arranged over the second semiconductor layer. A first conductive layer is arranged over the third gate layer. The first conductive layer is electrically connected to the second gate layer. The second semiconductor layer is arranged in the groove pattern.

In an embodiment, the first interlayer insulating layer may include a first inorganic protection layer including an opening upwardly exposing a portion of an upper surface of the second gate layer, and a second inorganic protection layer arranged over the first inorganic protection layer and covering an inner surface of the opening and a portion of the upper surface of the second gate layer.

In an embodiment, a thickness of the second inorganic protection layer may be less than a thickness of the first inorganic protection layer.

In an embodiment, the first inorganic protection layer may include a first-1 inorganic protection layer having a first-1 thickness and disposed directly on the second gate layer, and a first-2 inorganic protection layer having a first-2 thickness greater than the first-1 thickness and disposed directly on the first-1 inorganic protection layer.

In an embodiment, the first inorganic protection layer may include a first-1 inorganic protection layer including silicon nitride (SiNₓ) and disposed directly on the second gate layer, and a first-2 inorganic protection layer including silicon oxide (SiOₓ) and disposed directly on the first-1 inorganic protection layer.

In an embodiment, the second inorganic protection layer may include a single layer including SiNₓ.

In an embodiment, a thickness of the second inorganic protection layer may be less than or equal to the first-1 thickness.

In an embodiment, the second inorganic protection layer may include a second-1 inorganic protection layer having a second-1 thickness and disposed directly on the first inorganic protection layer, and a second-2 inorganic protection layer having a second-2 thickness greater than or equal to the second-1 thickness and disposed directly on the second-1 inorganic protection layer.

In an embodiment, the second-2 thickness may be less than a thickness of the first inorganic protection layer.

In an embodiment, the second inorganic protection layer may include a second-1 inorganic protection layer including SiNₓ and disposed directly on the first inorganic protection layer, and a second-2 inorganic protection layer including SiOₓ and disposed directly on the second-1 inorganic protection layer.

In an embodiment, a thickness of a portion of the first interlayer insulating layer arranged between the second gate layer and the second semiconductor layer may be less than a thickness of a remaining portion of the first interlayer insulating layer.

In an embodiment, the first conductive layer may be electrically connected to the second semiconductor layer.

In an embodiment, the display apparatus may further include a pixel electrode arranged over the first conductive layer, wherein the second semiconductor layer may be electrically connected to the pixel electrode.

According to an embodiment of the present disclosure, a display apparatus includes a substrate. A first semiconductor layer is arranged over the substrate. A first gate layer is arranged over the first semiconductor layer. A second gate layer is arranged over the first gate layer. A first interlayer insulating layer is arranged over the second gate layer. The first interlayer insulating layer includes a groove pattern having a downwardly concave shape. A second semiconductor layer is arranged over the first interlayer insulating layer and including an oxide semiconductor. A third gate layer is arranged over the second semiconductor layer and is electrically connected to the second gate layer. A first conductive layer is arranged over the third gate layer and electrically connected to the second semiconductor layer. The second semiconductor layer is arranged in the groove pattern.

In an embodiment, the first interlayer insulating layer may include a first inorganic protection layer including an opening upwardly exposing a portion of an upper surface of the second gate layer, and a second inorganic protection layer arranged over the first inorganic protection layer and covering an inner surface of the opening and a portion of the upper surface of the second gate layer.

In an embodiment, a thickness of the second inorganic protection layer may be less than a thickness of the first inorganic protection layer.

In an embodiment, the first inorganic protection layer may include a first-1 inorganic protection layer having a first-1 thickness and disposed directly on the second gate layer, and a first-2 inorganic protection layer having a first-2 thickness greater than the first-1 thickness and disposed directly on the first-1 inorganic protection layer.

In an embodiment, the first inorganic protection layer may include a first-1 inorganic protection layer including silicon nitride (SiNₓ) and disposed directly on the second gate layer, and a first-2 inorganic protection layer including silicon oxide (SiOₓ) and disposed directly on the first-1 inorganic protection layer.

In an embodiment, a thickness of a portion of the first interlayer insulating layer arranged between the second gate layer and the second semiconductor layer may be less than a thickness of a remaining portion of the first interlayer insulating layer.

According to an embodiment of the present disclosure, a method of manufacturing a display apparatus includes forming a first semiconductor layer over a substrate, forming a first gate layer over the first semiconductor layer, forming a second gate layer over the first gate layer, forming a first interlayer insulating layer including a concave pattern over the second gate layer, forming a second semiconductor layer including an oxide semiconductor over the concave pattern, forming a third gate layer over the second semiconductor layer, and forming a first conductive layer over the third gate layer, wherein the concave pattern corresponds to a shape of the second semiconductor layer.

In an embodiment, the forming of the first interlayer insulating layer including the concave pattern may include forming a first inorganic protection layer over the second gate layer, forming an opening in the first inorganic protection layer such that a portion of an upper surface of the second gate layer is upwardly exposed, and forming a second inorganic protection layer covering the first inorganic protection layer, a portion of the upper surface of the second gate layer, and an inner surface of the opening.

In an embodiment, the forming of the first inorganic protection layer may include forming a first-1 inorganic protection layer having a first-1 thickness and including silicon nitride (SiNₓ), and forming a first-2 inorganic protection layer having a first-2 thickness and including silicon oxide (SiOₓ).

In an embodiment, the first-2 thickness may be greater than the first-1 thickness.

In an embodiment, the first conductive layer may be electrically connected to the second gate layer by a through hole defined in the second gate layer and may be electrically connected to the second semiconductor layer by a through hole defined in the second semiconductor layer.

In an embodiment, the first conductive layer may be electrically connected to the second semiconductor layer by a through hole defined in the second semiconductor layer, and the third gate layer may be electrically connected to the second gate layer by a through hole defined in the second gate layer.

According to one or more embodiments, an electronic apparatus includes a memory storing a command, a processor performing an operation according to the command and generating a control command, and a display panel displaying a screen according to the control command. The display panel includes a substrate, a first semiconductor layer arranged over the substrate, a first gate layer arranged over the first semiconductor layer, a second gate layer arranged over the first gate layer and a first interlayer insulating layer arranged over the second gate layer. The first interlayer insulating layer includes a groove pattern having a downwardly concave shape. A second semiconductor layer is arranged over the first interlayer insulating layer and includes an oxide semiconductor. A third gate layer is arranged over the second semiconductor layer. A first conductive layer is arranged over the third gate layer and electrically connected to the second gate layer. A portion of the second semiconductor layer is arranged in the groove pattern.

In an embodiment, the first interlayer insulating layer may include a first inorganic protection layer including an opening upwardly exposing a portion of an upper surface of the second gate layer, and a second inorganic protection layer arranged over the first inorganic protection layer and covering an inner surface of the opening and a portion of the upper surface of the second gate layer.

### BRIEF DESCRIPTION OF THE DRAWINGS

The above and other aspects, features, and advantages of certain non-limiting embodiments of the present disclosure will be more apparent from the following description taken in conjunction with the accompanying drawings, in which:

FIG. 1 is a plan view schematically illustrating a display panel included in a display apparatus according to an embodiment of the present disclosure;

FIG. 2 is an example of an equivalent circuit diagram schematically illustrating a subpixel of the display apparatus of FIG. 1 according to an embodiment of the present disclosure;

FIG. 3 is another example of an equivalent circuit diagram schematically illustrating a subpixel of the display apparatus of FIG. 1 according to an embodiment of the present disclosure;

FIG. 4 is another example of an equivalent circuit diagram schematically illustrating a subpixel of the display apparatus of FIG. 1 according to an embodiment of the present disclosure;

FIG. 5 is an example of a cross-sectional view schematically illustrating a cross-section of a subpixel and a peripheral area of the subpixel of FIG. 1 according to an embodiment of the present disclosure;

FIG. 6 is an example of a cross-sectional view schematically illustrating a cross-section of a subpixel and a peripheral area of the subpixel of FIG. 1 according to an embodiment of the present disclosure;

FIGS. 7 to 10 are cross-sectional views schematically illustrating a common process of manufacturing a second-type thin film transistor of FIG. 5 or 6 according to embodiments of the present disclosure;

FIGS. 11 and 12 are cross-sectional views schematically illustrating a common process of manufacturing the second-type thin film transistor of FIG. 5 or 6 according to embodiments of the present disclosure;

FIGS. 13 to 15 are cross-sectional views schematically illustrating a common process of manufacturing the second-type thin film transistor of FIG. 5 or 6 according to embodiments of the present disclosure;

FIG. 16 is a graph illustrating measurement of a change in a threshold voltage of a first thin film transistor depending on a change in a thickness of a first-1 inorganic protection layer of FIG. 7 and the like according to an embodiment of the present disclosure;

FIG. 17 is a graph illustrating a subthreshold slope (SS) of a first thin film transistor depending on a change in a parasitic capacitance thereof according to an embodiment of the present disclosure;

FIG. 18 is a graph illustrating a change in the I-V curve of the first thin film transistor depending on a change in the SS according to an embodiment of the present disclosure;

FIG. 19 is a plan view schematically illustrating a layout of a portion of the display area of FIG. 1 according to an embodiment of the present disclosure;

FIGS. 20 to 29 are plan views schematically illustrating layouts illustrated in FIG. 19 in a stacking order thereof according to embodiments of the present disclosure;

FIG. 30 is a plan view schematically illustrating a layout of a portion of the display area of FIG. 1 according to an embodiment of the present disclosure;

FIGS. 31 to 39 are plan views schematically illustrating layouts illustrated in FIG. 30 in a stacking order thereof according to embodiments of the present disclosure; and

FIG. 40 is a block diagram of an electronic apparatus according to an embodiment of the present disclosure.

### DETAILED DESCRIPTION OF EMBODIMENTS

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, non-limiting embodiments are merely described below, by referring to the figures, to explain aspects of the present description. As used herein, the term “and/or” includes any and all combinations of one or more of the associated listed items. Throughout the present disclosure, the expression “at least one of a, b or c” indicates only a, only b, only c, both a and b, both a and c, both b and c, all of a, b, and c, or variations thereof.

The present disclosure may include various embodiments and modifications, and particular non-limiting embodiments thereof are illustrated in the drawings and will be described herein in detail. The effects and features of the present disclosure and methods of achieving them will become apparent with reference to embodiments described below in detail together with the drawings. However, the present disclosure is not limited to the embodiments described below and may be implemented in various forms.

Hereinafter, non-limiting embodiments will be described in detail with reference to the accompanying drawings, and in the following description, like reference numerals will denote like elements and redundant descriptions thereof will be omitted for conciseness.

It will be understood that although terms such as “first” and “second” may be used herein to describe various elements, these elements should not be limited by these terms and these terms are only used to distinguish one element from another element. Also, as used herein, the singular forms “a,” “an,” and “the” are intended to include the plural forms as well, unless the context clearly indicates otherwise.

It will be understood that when an element such as a layer, a region, or a plate is referred to as being “on” another element, it may be “directly on” the element or may be “indirectly on” the other element with one or more intervening elements therebetween. When an element such as a layer, a region, or a plate is referred to as being “directly on” another element, no intervening elements may be present.

Also, sizes of components in the drawings may be exaggerated for convenience of description. In other words, because the sizes and shapes of components in the drawings may be arbitrarily illustrated for convenience of description, embodiments of the present disclosure are not necessarily limited thereto.

It will be understood that terms such as “comprise,” “include,” and “have” used herein specify the presence of stated features or elements, but do not preclude the presence or addition of one or more other features or elements.

When a certain embodiment may be implemented differently, a particular process order may be performed differently from the described order. For example, two consecutively described processes may be performed substantially at the same time or performed in an order opposite to the described order.

As used herein, “A and/or B” represents the case of A, B, or A and B. Also, “at least one of A and B” represents the case of A, B, or A and B.

It will be understood that when a layer, region, or component is referred to as being “connected to” another layer, region, or component, it may be “directly connected to” the other layer, region, or component or may be “indirectly connected to” the other layer, region, or component with one or more intervening layers, regions, or components therebetween. For example, it will be understood that when a layer, region, or component is referred to as being “electrically connected to” another layer, region, or component, it may be “directly electrically connected to” the other layer, region, or component or may be “indirectly electrically connected to” the other layer, region, or component with one or more intervening layers, regions, or components therebetween.

Also, herein, the X axis, the Y axis, and the Z axis are not necessarily limited to three axes of the rectangular coordinate system and may be interpreted in a broader sense. For example, the X axis, the Y axis, and the X axis may be perpendicular to one another or may represent different directions that are not perpendicular to one another.

Hereinafter, a display apparatus, a method of manufacturing the display apparatus, and an electronic apparatus according to an embodiment will be described in detail based on the above descriptions.

The present disclosure concerns a display apparatus that includes a first interlayer insulating layer disposed between a second gate layer and a third gate layer. The first interlayer insulating layer has a groove pattern having a downwardly concave shape. A second semiconductor layer is disposed in the groove pattern. The groove pattern may have a shape corresponding to the shape of the second semiconductor layer. The downwardly concave shape of the groove pattern increases the distance between the second semiconductor layer disposed in the groove pattern and the conductive material of the third gate layer. Therefore, a parasitic capacitance between the second semiconductor layer and the third gate layer may be prevented or reduced to increase the electrical characteristics of the thin film transistor.

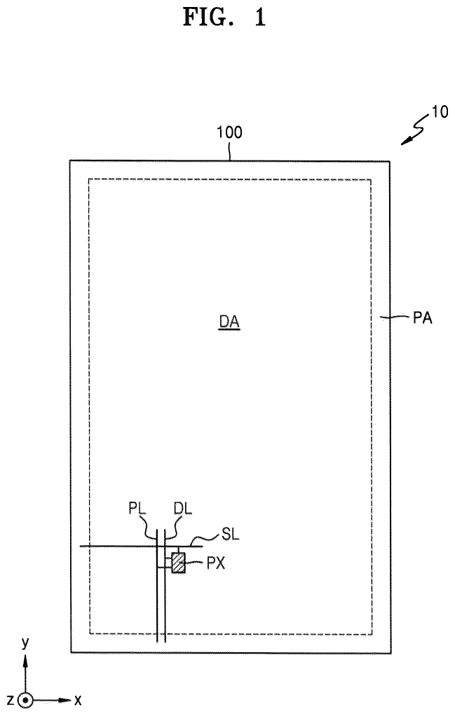

FIG. 1 is a plan view schematically illustrating a display panel included in a display apparatus according to an embodiment.

As illustrated in FIG. 1, a display panel 10 may include a display area DA and a peripheral area PA located outside the display area DA (e.g., in a plan view). In FIG. 1, the display area DA is illustrated as having a rectangular shape. However, embodiments of the present disclosure are not necessarily limited thereto. For example, the display area DA may have any of various shapes such as a circular shape, elliptical shape, polygonal shape, or particular figure shape (e.g., in a plan view).

The display area DA may be an area for displaying an image, and a plurality of subpixels PX may be arranged in the display area DA. Each of the plurality of subpixels PX may include a display device such as an organic light emitting device. In an embodiment, each of the plurality of subpixels PX may emit, for example, red, green, or blue light. The subpixel PX may be connected to (e.g., electrically connected thereto) a pixel circuit including a thin film transistor (TFT), a storage capacitor, and/or the like. The pixel circuit may be connected to (e.g., electrically connected to) a scan line SL configured to transmit a scan signal, a data line DL intersecting with the scan line SL and configured to transmit a data signal, and a driving voltage line PL configured to supply a driving voltage. For example, in an embodiment the data line DL and the driving voltage line PL may extend in a y-axis direction (hereinafter referred to as a first direction), and the scan line SL may extend in an x-axis direction (hereinafter referred to as a second direction).

The subpixel PX may emit light with a brightness corresponding to an electrical signal received from the data line DL. The display area DA may display a certain image through the light emitted from the subpixel PX. For example, the subpixel P may be defined as an emission area emitting any one of red light, green light, and blue light.

The peripheral area PA may be an area in which a subpixel PX is not arranged and may be an area that does not display an image. A power supply line for driving the subpixel PX may be located in the peripheral area PA. Also, pads may be arranged in the peripheral area PA, and a printed circuit board including a driving circuit unit or an integrated circuit (IC) device such as a driver IC may be electrically connected to the pads in the peripheral area PA.

For reference, since the display panel 10 includes a substrate 100, it may be considered that the substrate 100 may include the display area DA and the peripheral area PA. The substrate 100 will be described below in detail.

A plurality of transistors may be arranged in the display area DA. Regarding the plurality of transistors, depending on the type (e.g., N type or P type) and/or the operation condition of the transistor, a first terminal of the transistor may be a source electrode or a drain electrode, and a second terminal thereof may be an electrode different from the first terminal among the source electrode and the drain electrode. For example, in an embodiment in which the first terminal is a source electrode, the second terminal may be a drain electrode.

Hereinafter, an organic light emitting display apparatus will be described as an example of a display apparatus according to an embodiment. However, embodiments of the present disclosure are not necessarily limited thereto. For example, in an embodiment, the display apparatus may be an inorganic light emitting display apparatus (or an inorganic electroluminescence (EL) display apparatus) or a display apparatus such as a quantum dot light emitting display apparatus. For example, an emission layer included in the display apparatus may include an organic material or an inorganic material. In some embodiments, the display apparatus may include an emission layer and quantum dots located on the path of light emitted from the emission layer.

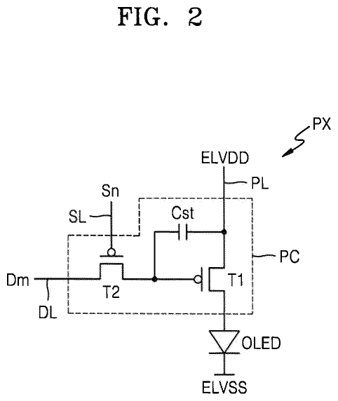

FIG. 2 is an example of an equivalent circuit diagram schematically illustrating a subpixel of the display apparatus of FIG. 1. The equivalent circuit diagram of FIG. 2 may be a basic equivalent circuit diagram, and at least one equivalent circuit diagram among the equivalent circuit diagrams variously modified by applying the equivalent circuit diagram of FIG. 2 may be applied to a display apparatus according to an embodiment.

For convenience of description, a pMOS-type thin film transistor is illustrated in FIG. 2. However, embodiments of the present disclosure are not necessarily limited thereto and the pixel circuit may be variously modified.

As illustrated in FIG. 2, each subpixel PX may include a pixel circuit PC connected to (e.g., electrically connected thereto) a scan line SL and a data line DL and a light emitting device OLED connected to the pixel circuit PC.

For example, in an embodiment the pixel circuit PC may include a first thin film transistor T1, a second thin film transistor T2, and a storage capacitor Cst. The second thin film transistor T2 may be electrically connected to the scan line SL and the data line DL and may be configured to transmit a data signal Dm input from the data line DL to the first thin film transistor T1 according to a scan signal Sn input from the scan line SL.

For example, in an embodiment the first thin film transistor T1 may be a driving thin film transistor, and the second thin film transistor T2 may be a switching thin film transistor.

For example, the storage capacitor Cst may be connected to (e.g., electrically connected thereto) the second thin film transistor T2 and a driving voltage line PL and may be configured to store a voltage corresponding to the difference between a voltage received from the second thin film transistor T2 and a first power voltage ELVDD supplied to the driving voltage line PL.

For example, the first thin film transistor T1 may be connected to (e.g., electrically connected thereto) the driving voltage line PL and the storage capacitor Cst and may be configured to control a driving current flowing from the driving voltage line PL through the light emitting device OLED in response to a voltage value stored in the storage capacitor Cst. The light emitting device OLED may emit light with a certain brightness according to the driving current.

The light emitting device OLED may receive a second power voltage ELVSS (e.g., a common voltage). For example, the light emitting device OLED may receive the second power voltage ELVSS (e.g., the common voltage) through an opposite electrode (e.g., cathode), and the light emitting device OLED may emit light with a certain brightness by the driving current according to the voltage difference between the first power voltage ELVDD (e.g., the driving voltage) and the second power voltage ELVSS (e.g., the common voltage).

FIG. 2 illustrates an embodiment in which the pixel circuit PC includes two thin film transistors and one storage capacitor Cst. However, embodiments of the present disclosure are not necessarily limited thereto. For example, in some embodiments the pixel circuit PC may include two or more capacitors and may also include three or more thin film transistors.

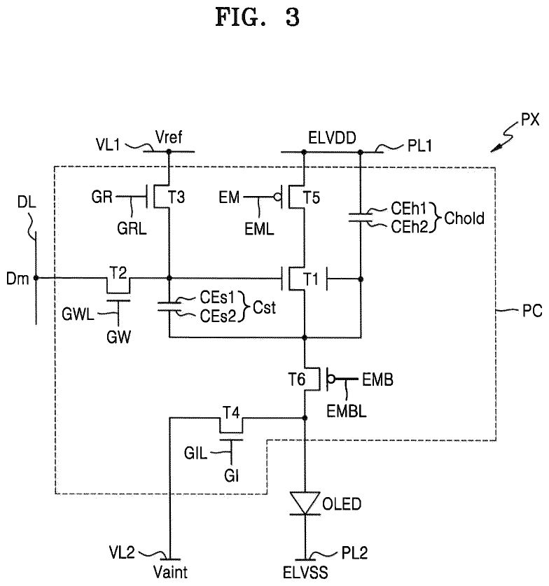

FIG. 3 is an example of an equivalent circuit diagram schematically illustrating a subpixel of the display apparatus of FIG. 1. The equivalent circuit diagram of FIG. 3 may be an example of one of the equivalent circuit diagrams variously modified by applying the equivalent circuit diagram of FIG. 2.

As illustrated in FIG. 3, each subpixel PX may include a pixel circuit PC connected to (e.g., electrically connected thereto) a data line DL and a plurality of scan lines GWL, GRL, GIL, EML, and EMBL corresponding to the scan line SL of FIG. 2 and a light emitting device OLED connected to (e.g., electrically connected thereto) the pixel circuit PC. Scan signals GW, GR, GI, EM, and EMB of FIG. 3 may be transmitted through the plurality of scan lines GWL, GRL, GIL, EML, and EMBL.

A first thin film transistor T1 may receive a data signal Dm and transmit a driving current to the light emitting device OLED based on the data signal Dm. For example, in an embodiment the first thin film transistor T1 may have a dual-gate structure including two gate electrodes.

For example, in an embodiment the first thin film transistor T1 may be an nMOS thin film transistor and may be a thin film transistor including an oxide semiconductor layer.

For example, one of the gate electrodes of the first thin film transistor T1 may function as an upper gate in the dual gate structure, and the other one of the gate electrodes of the first thin film transistor T1 may function as a lower gate in the dual gate structure.

For example, in an embodiment the upper gate electrode of the first thin film transistor T1 may be electrically connected to a second thin film transistor T2, a storage capacitor Cst, and a third thin film transistor T3. For example, the upper gate electrode of the first thin film transistor T1 may be electrically connected to one of the source-drain electrodes of the second thin film transistor T2, one of the electrodes of the storage capacitor Cst, and one of the source-drain electrodes of the third thin film transistor T3.

For example, in an embodiment the third thin film transistor T3 may be a first initialization thin film transistor.

In an embodiment, the second thin film transistor T2 may receive a data signal Dm from the data line DL and transmit the data signal Dm to the first thin film transistor T1. For example, the second thin film transistor T2 may include a gate electrode that receives a first scan signal GW. For example, one of the source-drain electrodes of the second thin film transistor T2 may be electrically connected to the upper gate electrode of the first thin film transistor T1, a first electrode CEs1 among the electrodes of the storage capacitor Cst, and one of the source-drain electrodes of the third thin film transistor T3. For example, the other one of the source-drain electrodes of the second thin film transistor T2 may be electrically connected to the data line DL.

For example, in an embodiment the second thin film transistor T2 may be an nMOS thin film transistor and may be a thin film transistor including an oxide semiconductor layer.

In an embodiment, the third thin film transistor T3 may receive a reference voltage Vref from a reference voltage line VL1 and transmit the reference voltage Vref to the storage capacitor Cst. For example, the third thin film transistor T3 may include a gate electrode that receives a second scan signal GR from a scan line GRL. For example, one of the source-drain electrodes of the third thin film transistor T3 may be electrically connected to the first thin film transistor T1, the second thin film transistor T2, and the storage capacitor Cst. For example, the other one of the source-drain electrodes of the third thin film transistor T3 may be electrically connected to the reference voltage line VL1 and may receive the reference voltage Vref from the reference voltage line VL1.

For example, in an embodiment the third thin film transistor T3 may be an nMOS thin film transistor and may be a thin film transistor including an oxide semiconductor layer.

In an embodiment, the storage capacitor Cst may receive the reference voltage Vref and maintain the same for a certain time. For example, the storage capacitor Cst may maintain a voltage equal to the difference between the reference voltage Vref and the data signal Dm for a certain time. For example, the first electrode CEs1 of the storage capacitor Cst may be electrically connected to the upper gate electrode of the first thin film transistor T1, one of the source-drain electrodes of the second thin film transistor T2, and one of the source-drain electrodes of the third thin film transistor T3. For example, a second electrode CEs2 of the storage capacitor Cst may be electrically connected to one of the source-drain electrodes of the first thin film transistor T1, one of the source-drain electrodes of a sixth thin film transistor T6, and a second electrode CEh2 among the electrodes of a hold capacitor Chold.

In an embodiment, the hold capacitor Chold may be electrically connected to the first thin film transistor T1, the third thin film transistor T3, the sixth thin film transistor T6, and a power line PL1. A first electrode CEh1 of the hold capacitor Chold may be electrically connected to the power line PL1 and may receive a first power voltage ELVDD from the power line PL1. The second electrode CEh2 of the hold capacitor Chold may be electrically connected to the lower gate electrode of the first thin film transistor T1, the other one of the source-drain electrodes of the first thin film transistor T1, and the second electrode CEs2 of the storage capacitor Cst.

In an embodiment, a fourth thin film transistor T4 may receive an initialization voltage Vaint from an initialization voltage line VL2 and transmit the initialization voltage Vaint to the light emitting device OLED. For example, the fourth thin film transistor T4 may be a second initialization thin film transistor.

For example, the fourth thin film transistor T4 may include a gate electrode that receives a third scan signal GI from a scan line GIL. For example, one of the source-drain electrodes of the fourth thin film transistor T4 may be electrically connected to the sixth thin film transistor T6 and the light emitting device OLED. For example, one of the source-drain electrodes of the fourth thin film transistor T4 may be electrically connected to the other one of the source-drain electrodes of the sixth thin film transistor T6 and the light emitting device OLED. For example, the other one of the source-drain electrodes of the fourth thin film transistor T4 may be electrically connected to the initialization voltage line VL2 and may receive the initialization voltage Vaint from the initialization voltage line VL2.

For example, in an embodiment the fourth thin film transistor T4 may be an nMOS thin film transistor and may be a thin film transistor including an oxide semiconductor layer.

In an embodiment, a fifth thin film transistor T5 may receive the first power voltage ELVDD from the power line PL1 and transmit the first power voltage ELVDD to the first thin film transistor T1. For example, the fifth thin film transistor T5 may include a gate electrode that receives a fourth scan signal EM from a scan line EML.

For example, in an embodiment the fifth thin film transistor T5 may be a first emission control thin film transistor.

For example, one of the source-drain electrodes of the fifth thin film transistor T5 may be electrically connected to the other one of the source-drain electrodes of the first thin film transistor T16. For example, the other one of the source-drain electrodes of the fifth thin film transistor T5 may be electrically connected to the power line PL1 and may receive the first power voltage ELVDD from the power line PL1.

For example, in an embodiment the fifth thin film transistor T5 may be a pMOS thin film transistor and may be a thin film transistor including a semiconductor layer.

The sixth thin film transistor T6 may be electrically connected to the first thin film transistor T1, the hold capacitor Chold, the storage capacitor Cst, the fourth thin film transistor T4, and the light emitting device OLED.

For example, in an embodiment the sixth thin film transistor T6 may be a second emission control thin film transistor.

For example, the sixth thin film transistor T6 may include a gate electrode that receives a fifth scan signal EMB from a scan line EMBL. For example, one of the source-drain electrodes of the sixth thin film transistor T6 may be electrically connected to the other one of the source-drain electrodes of the first thin film transistor T1, the second electrode CEs2 of the storage capacitor Cst, and the second electrode CEh2 of the hold capacitor Chold. For example, the other one of the source-drain electrodes of the sixth thin film transistor T6 may be electrically connected to one of the source-drain electrodes of the fourth thin film transistor T4 and the light emitting device OLED.

For example, in an embodiment the sixth thin film transistor T6 may be a pMOS thin film transistor and may be a thin film transistor including a semiconductor layer.

The light emitting device OLED may receive a second power voltage ELVSS (e.g., a common voltage) through a second power line PL2. For example, the light emitting device OLED may receive the second power voltage ELVSS (e.g., the common voltage) through an opposite electrode (e.g., cathode), and the light emitting device OLED may emit light with a certain brightness by the driving current according to the voltage difference between the first power voltage ELVDD (e.g., the driving voltage) and the second power voltage ELVSS (e.g., the common voltage).

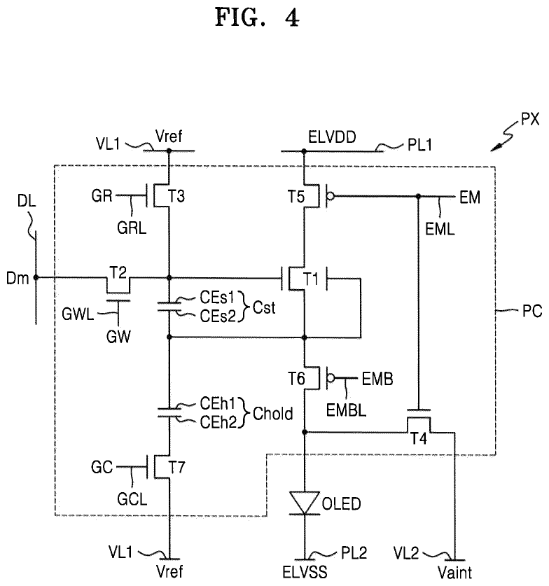

FIG. 4 is an example of an equivalent circuit diagram schematically illustrating a subpixel of the display apparatus of FIG. 1. The equivalent circuit diagram of FIG. 4 may be an example of one of the equivalent circuit diagrams variously modified by applying the equivalent circuit diagram of FIG. 2. For convenience of description, redundant descriptions of FIG. 4 with the descriptions of FIG. 3 may be omitted for conciseness.

As illustrated in FIG. 4, a scan signal EM transmitted to a fourth thin film transistor T4 may be the same signal as a scan signal EM transmitted to a fifth thin film transistor T5.

Unlike the fourth thin film transistor T4 and the fifth thin film transistor T5 of FIG. 3 electrically connected to different scan lines GIL and EML, the fourth thin film transistor T4 and the fifth thin film transistor T5 of FIG. 4 may be electrically connected to the same scan line EML.

The equivalent circuit diagram of FIG. 4 may further include a seventh thin film transistor T7 for transmitting a reference voltage Vref to a hold capacitor Chold. For example, the seventh thin film transistor T7 may include a gate electrode that receives a sixth scan signal GC from a scan line GCL. For example, the reference voltage Vref received by the seventh thin film transistor T7 may be the same voltage as a reference voltage Vref received by a third thin film transistor T3. For example, the seventh thin film transistor T7 and the third thin film transistor T3 may be electrically connected to the same reference voltage line VL1.

Unlike in the equivalent circuit diagram of FIG. 3, a first electrode CEh1 of the hold capacitor Chold of FIG. 4 may be electrically connected to the seventh thin film transistor T7, not to a power line PL1.

Unlike in the equivalent circuit diagram of FIG. 3, a sixth thin film transistor T6 may be an nMOS thin film transistor and may be a thin film transistor including an oxide semiconductor layer.

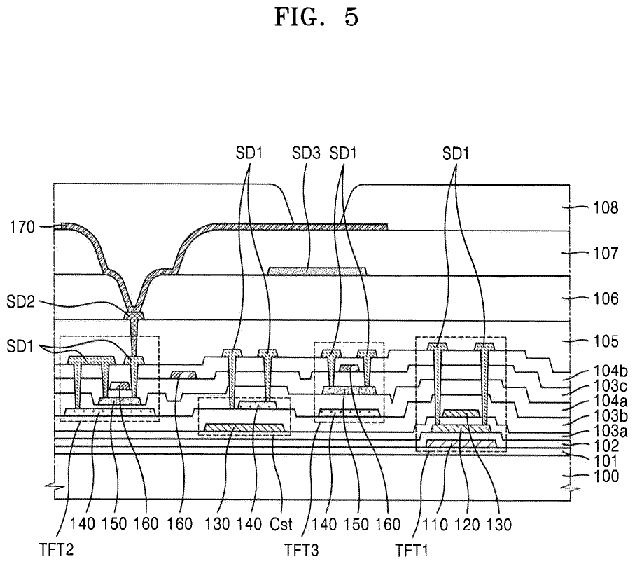

FIG. 5 is an example of a cross-sectional view schematically illustrating a cross-section of a subpixel and a peripheral area of the subpixel of FIG. 1.

As described above, the substrate 100 may include areas corresponding to the display area DA and the peripheral area PA outside the display area DA (e.g., in a plan view). The substrate 100 may include various materials having flexible or bendable characteristics. For example, in an embodiment the substrate 100 may include glass, metal, or polymer resin. Also, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate.

The substrate 100 may be variously modified such as including a multilayer structure including two layers including the polymer resin and a barrier layer arranged between the two layers and including an inorganic material (e.g., silicon oxide, silicon nitride, or silicon oxynitride).

A barrier layer 101 may be arranged over the substrate 100 (e.g., directly on an upper surface thereof). In an embodiment, the barrier layer 101 may include an inorganic material such as silicon oxide, silicon nitride, and/or silicon oxynitride and may be arranged between the substrate 100 and a lower metal layer 110. In an embodiment, the barrier layer 101 may have a shape corresponding to the entire surface of the substrate 100 and may be formed through chemical vapor deposition (CVD) or atomic layer deposition (ALD). The barrier layer 101 may prevent diffusion of impurity ions, prevent penetration of moisture or external air, and planarize the surface.

The lower metal layer 110 may be arranged over the barrier layer 101 (e.g., directly on an upper surface thereof). In an embodiment, the lower metal layer 110 may be arranged under a first semiconductor layer 120 and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li) calcium (Ca), titanium (Ti), tungsten (W), and copper (Cu). For example, in the plan view, at least a portion of the lower metal layer 110 may overlap at least a portion of the first semiconductor layer 120. For example, in the plan view, at least a portion of the lower metal layer 110 may overlap at least a portion of a first gate layer 130.

A buffer layer 102 may be arranged over (e.g., directly thereon) the lower metal layer 110. In an embodiment, the buffer layer 102 may include an inorganic material such as silicon oxide, silicon nitride, and/or silicon oxynitride and may be arranged between the substrate 100 and the lower metal layer 110. The buffer layer 102 may be formed through chemical vapor deposition (CVD) or atomic layer deposition (ALD). The buffer layer 102 may prevent diffusion of impurities ions, prevent penetration of moisture or external air, and adjust a heat supply rate during a crystallization process for forming the first semiconductor layer 120, such that the first semiconductor layer 120 may be uniformly crystallized.

The first semiconductor layer 120 may be arranged over the buffer layer 102 (e.g., directly on an upper surface thereof). The first semiconductor layer 120 may include polysilicon (e.g., low-temperature polycrystalline silicon) and may include a channel area not doped with dopants and a source-drain area formed by doping both sides of the channel area. In an embodiment, the dopants may vary depending on the types of thin film transistors and may be N-type dopants or P-type dopants.

A first gate insulating layer 103a may be arranged over (e.g., directly thereon) the first semiconductor layer 120. The first gate insulating layer 103a may be configured to secure insulation between the first semiconductor layer 120 and the first gate layer 130. In an embodiment, the first gate insulating layer 103a may include an inorganic material such as silicon oxide, silicon nitride, and/or silicon oxynitride and may be arranged between the first semiconductor layer 120 and the first gate layer 130. The first gate insulating layer 103a may have a shape corresponding to the entire surface of the substrate 100 and may have structure in which contact holes are formed at preset portions. The first gate insulating layer 103a may be formed through chemical vapor deposition (CVD) or atomic layer deposition (ALD).

The first gate layer 130 may be arranged over the first gate insulating layer 103a (e.g., directly on an upper surface thereof). In an embodiment, the first gate layer 130 may be arranged at a position vertically overlapping the first semiconductor layer 120 and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

A second gate insulating layer 103b may be arranged over (e.g., directly thereon) the first gate layer 130. The second gate insulating layer 103b may be configured to secure insulation between the first gate layer 130 and a second gate layer 140. In an embodiment, the second gate insulating layer 103b may include an inorganic material such as silicon oxide, silicon nitride, and/or silicon oxynitride and may be arranged between the first gate layer 130 and the second gate layer 140. The second gate insulating layer 103b may have a shape corresponding to the entire surface of the substrate 100 and may have structure in which contact holes are formed at preset portions. The second gate insulating layer 103b may be formed through chemical vapor deposition (CVD) or atomic layer deposition (ALD).

The second gate layer 140 may be arranged over the second gate insulating layer 103b (e.g., directly on an upper surface thereof). In an embodiment, the second gate layer 140 may be arranged at a position overlapping the first semiconductor layer 130 or the second semiconductor layer 150 in the plan view and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

A first interlayer insulating layer 104a may be arranged over (e.g., directly thereon) the second gate layer 140 and the second gate insulating layer 103b. The first interlayer insulating layer 104a may cover the second gate layer 140. The first interlayer insulating layer 104a may include an inorganic material. For example, in an embodiment the first interlayer insulating layer 104a may include a metal oxide or a metal nitride, and particularly, the inorganic material may include silicon oxide (SiO2), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). For example, the first interlayer insulating layer 104a may include a dual structure of SiOₓ/SiN_{y} or SiNₓ/SiO_{y}.

A second semiconductor layer 150 may be arranged over (e.g., directly thereon) the first interlayer insulating layer 104a. In an embodiment, the second semiconductor layer 150 may include polysilicon (e.g., low-temperature polycrystalline silicon) or may be an oxide semiconductor layer (e.g., IGZO or IZO). The second semiconductor layer 150 may include a channel area that is not doped with dopants or is doped with a relatively small amount of dopants, and a source-drain area that is formed by doping both sides of the channel area with a relatively large amount of dopants (compared to the amount of dopants in the channel area).

For example, in an embodiment in which the second semiconductor layer 150 includes polysilicon, the dopants may vary depending on the type of the thin film transistor and may be N-type dopants or P-type dopants. For example, in an embodiment in which the second semiconductor layer 150 is an oxide semiconductor layer, the second semiconductor layer 150 may generally be an n-type semiconductor layer.

A third gate insulating layer 103c may be arranged over (e.g., directly thereon) the second semiconductor layer 150 and the first interlayer insulating layer 104a. The third gate insulating layer 103c may be configured to secure insulation between the second semiconductor layer 150 and a third gate layer 160. In an embodiment, the third gate insulating layer 103c may include an inorganic material such as silicon oxide, silicon nitride, and/or silicon oxynitride and may be arranged between the second semiconductor layer 150 and the third gate layer 160. The third gate insulating layer 103c may have a shape corresponding to the entire surface of the substrate 100 and may have structure in which contact holes are formed at preset portions. The third gate insulating layer 103c may be formed through chemical vapor deposition (CVD) or atomic layer deposition (ALD).

The third gate layer 160 may be arranged over the third gate insulating layer 103c (e.g., directly on an upper surface thereof). In an embodiment, the third gate layer 160 may be arranged at a position vertically overlapping the second semiconductor layer 150 and may include at least one metal among molybdenum (Mo), aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), titanium (Ti), tungsten (W), and copper (Cu).

A second interlayer insulating layer 104b may be arranged over (e.g., directly thereon) the third gate layer 160 and the third gate insulating layer 103c. The second interlayer insulating layer 104b may cover the third gate layer 160 and/or the first interlayer insulating layer 104a. The second interlayer insulating layer 104b may include an inorganic material. For example, in an embodiment the second interlayer insulating layer 104b may include a metal oxide or a metal nitride, and particularly, the inorganic material may include silicon oxide (SiO2), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). For example, the second interlayer insulating layer 104b may include a dual structure of SiOₓ/SiN_{y} or SiNₓ/SiO_{y}.

A first conductive layer SD1 may be arranged over the second interlayer insulating layer 104b (e.g., directly on an upper surface thereof). In an embodiment, the first conductive layer SD1 may function as an electrode connected to the source-drain area of the first semiconductor layer 120 and/or the second semiconductor layer 150 through a through hole included in the second interlayer insulating layer 104b and/or a through hole included in the first interlayer insulating layer 104a and the second interlayer insulating layer 104b.

In an embodiment, the first conductive layer SD1 may include one or more metals among aluminum (Al), platinum (Pt), palladium (Pd), silver (Ag), magnesium (Mg), gold (Au), nickel (Ni), neodymium (Nd), iridium, chromium (Cr), lithium (Li), calcium (Ca), molybdenum (Mo), titanium (Ti), tungsten (W), and copper (Cu). For example, the first conductive layer SD1 may include a Ti layer, an Al layer, and/or a Cu layer. For example, the first conductive layer SD1 may include a Ti/Al/Ti structure.

A first organic insulating layer 105 may be arranged over (e.g., directly thereon) the first conductive layer SD1. The first organic insulating layer 105 may be an organic insulating layer functioning as a planarization layer by covering the upper portion of the first conductive layer SD1 and having a substantially flat upper surface. In an embodiment, the first organic insulating layer 105 may include, for example, an organic material such as acryl, benzocyclobutene (BCB), or hexamethyldisiloxane (HMDSO). The first organic insulating layer 105 may be variously modified, such as including a single layer or multiple layers.

A second conductive layer SD2 may be arranged over the first organic insulating layer 105 (e.g., directly on an upper surface thereof). In an embodiment, the second conductive layer SD2 may be connected to (e.g., directly connected thereto) a portion of the first conductive layer SD1, which is connected to the second semiconductor layer 140, through a through hole included in the first organic insulating layer 105, and thus may function as an electrode. In an embodiment, the second conductive layer SD2 may include one or more metals among aluminum (Al), platinum (Pt), palladium (Pd), silver (Ag), magnesium (Mg), gold (Au), nickel (Ni), neodymium (Nd), iridium, chromium (Cr), lithium (Li), calcium (Ca), molybdenum (Mo), titanium (Ti), tungsten (W), and copper (Cu). For example, the second conductive layer SD2 may include a Ti layer, an Al layer, and/or a Cu layer. For example, the second conductive layer SD2 may include a Ti/Al/Ti structure.

A second organic insulating layer 106 may be arranged over (e.g., directly thereon) the second conductive layer SD2 and the first organic insulating layer 105. The second organic insulating layer 106 may be an organic insulating layer functioning as a planarization layer by covering the upper portion of the second conductive layer SD2 and having a substantially flat upper surface. In an embodiment, the second organic insulating layer 106 may include, for example, an organic material such as acryl, benzocyclobutene (BCB), or hexamethyldisiloxane (HMDSO). The second organic insulating layer 106 may be variously modified, such as including a single layer or multiple layers.

A third conductive layer SD3 may be arranged over the second organic insulating layer 106 (e.g., directly on an upper surface thereof). The third conductive layer SD3 may function as a power line or the like and may also function as various lines. In an embodiment, the third conductive layer SD3 may include one or more metals among aluminum (Al), platinum (Pt), palladium (Pd), silver (Ag), magnesium (Mg), gold (Au), nickel (Ni), neodymium (Nd), iridium, chromium (Cr), lithium (Li), calcium (Ca), molybdenum (Mo), titanium (Ti), tungsten (W), and copper (Cu). For example, the third conductive layer SD3 may include a Ti layer, an Al layer, and/or a Cu layer. For example, the third conductive layer SD3 may include a Ti/Al/Ti structure. In some cases, the third conductive layer SD3 may be omitted.

A third organic insulating layer 107 may be arranged over the third conductive layer SD3 (e.g., directly on an upper surface thereof). The third organic insulating layer 107 may be an organic insulating layer functioning as a planarization layer by covering the upper portion of the third conductive layer SD3 and having a substantially flat upper surface. In an embodiment, the third organic insulating layer 107 may include, for example, an organic material such as acryl, benzocyclobutene (BCB), or hexamethyldisiloxane (HMDSO). The third organic insulating layer 107 may be variously modified, such as including a single layer or multiple layers. However, embodiments of the present disclosure are not necessarily limited thereto. For example, in some embodiments the third organic insulating layer 107 may be omitted.

A pixel electrode layer 170 may be arranged over (e.g., directly thereon) the third organic insulating layer 107. Alternatively, the pixel electrode layer 170 may be arranged over (e.g., directly thereon) the second organic insulating layer 106 in an embodiment in which the third organic insulating layer 107 is omitted.

In an embodiment, the pixel electrode layer 170 may be connected to (e.g., directly connected thereto) the second conductive layer SD2 through a contact hole formed in the second organic insulating layer 106 and the third organic insulating layer 107. A display device may be arranged over the pixel electrode layer 170. For example, in an embodiment the display device may be a light emitting device using an organic material. For example, in an embodiment the pixel electrode layer 170 may include a transparent conductive layer formed of a transparent conductive oxide such as ITO, In₂O₃, or IZO, and/or a reflective layer formed of a metal such as Al or Ag. For example, the pixel electrode layer 170 may have a three-layer structure of ITO/Ag/ITO.

A pixel definition layer 108 may be located over (e.g., directly thereon) the third organic insulating layer 107 and may be arranged to cover the edge of a pixel electrode implemented for each subpixel PX through the pixel electrode layer 170. For example, the pixel definition layer 108 may cover the edge of the pixel electrode implemented for each subpixel PX. In an embodiment, the pixel definition layer 108 may include an opening corresponding to the subpixel PX, and the opening may be formed to expose at least a central portion of the pixel electrode implemented for each subpixel. The opening may be defined by the pixel definition layer 108, such as inner edges of the pixel definition layer 108.

For example, in an embodiment the pixel definition layer 108 may include an organic material such as polyimide or hexamethyldisiloxane (HMDSO). A spacer may be arranged over the pixel definition layer 108.

In an embodiment, an intermediate layer and an opposite electrode may be arranged over the opening described above. The intermediate layer may include a low-molecular weight or high-molecular weight material, and in an embodiment in which the intermediate layer includes a low-molecular weight material, the intermediate layer may include a hole injection layer, a hole transport layer, an emission layer, an electron transport layer, and/or an electron injection layer. In an embodiment in which the intermediate layer includes a high-molecular weight material, the intermediate layer may generally have a structure including a hole transport layer and an emission layer.

The structure of the intermediate layer is not necessarily limited to the above structure and may have various structures. For example, at least one of the layers constituting the intermediate layer may be integrally formed like the opposite electrode. In an embodiment, the intermediate may include a layer patterned to correspond to each of a plurality of pixel electrodes.

In an embodiment, the opposite electrode may include a transparent conductive layer formed of a transparent conductive oxide such as ITO, In₂O₃, or IZO. The pixel electrode may be used as an anode, and the opposite electrode may be used as a cathode. However, the polarities of the electrodes may be applied in reverse.

In an embodiment, the opposite electrode may be arranged over the display area DA and may be arranged over the entire surface of the display area DA. The opposite electrode may be integrally formed to cover a plurality of pixels.

A first-type thin film transistor TFT1 may be a thin film transistor including the first semiconductor layer 120 described above. The first-type thin film transistor TFT1 may be a pMOS type or an nMOS type, depending on the type of the first semiconductor layer 120. For example, in an embodiment in which a second-type thin film transistor TFT2 illustrated in FIG. 5 is a pMOS type, the second-type thin film transistor TFT2 may be one of the fifth thin film transistor T5 and the sixth thin film transistor T6.

The second-type thin film transistor TFT2 and a third-type thin film transistor TFT3 may be thin film transistors including the second semiconductor layer 150 described above. The second-type thin film transistor TFT2 and the third-type thin film transistor TFT3 may be a pMOS type or an nMOS type, depending on the type of the second semiconductor layer 150. For example, in an embodiment in which the second semiconductor layer 150 includes an oxide semiconductor, the second-type thin film transistor TFT2 and the third-type thin film transistor TFT3 may be of an nMOS type according to the characteristics of the oxide semiconductor. For example, in an embodiment in which the second-type thin film transistor TFT2 and the third-type thin film transistor TFT3 illustrated in FIG. 5 are an nMOS type, the second-type thin film transistor TFT2 may be one of the first thin film transistor T1, the second thin film transistor T2, the third thin film transistor T3, and the fourth thin film transistor T4 and the third-type thin film transistor TFT3 may be one of the others.

A storage capacitor Cst may include a portion of a first gate layer and a portion of a second gate layer. A portion of the first gate layer and a portion of the second gate layer may be vertically spaced apart from each other. One electrode of the storage capacitor Cst may be one of a portion of the first gate layer and a portion of the second gate layer, and the other electrode of the storage capacitor Cst may be the other one thereof.

For example, the second-type thin film transistor TFT2 may be the first thin film transistor T1. In an embodiment in which the second-type thin film transistor TFT2 is the first thin film transistor T1, the second-type thin film transistor TFT2 may function as a lower gate electrode in a dual-gate structure as a portion of the second-type thin film transistor TFT2 in the second gate layer.

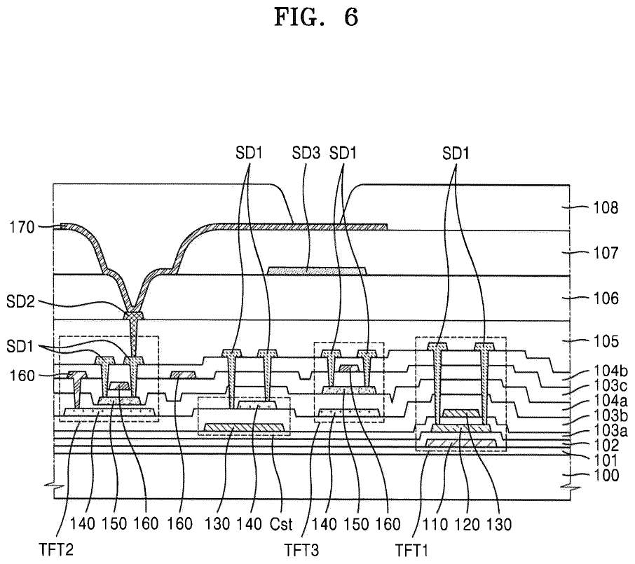

FIG. 6 is an example of a cross-sectional view schematically illustrating a cross-section of a subpixel and a peripheral area of the subpixel of FIG. 1. For reference, redundant descriptions of FIG. 6 with the descriptions of FIG. 5 may be omitted for conciseness.

In FIG. 5, the second semiconductor layer 150 and the second gate layer 140 are electrically connected to each other by the first conductive layer SD1 in the second-type thin film transistor TFT2. However, in FIG. 6, the second semiconductor layer 150 may be electrically connected to a first conductive layer SD1 and the second gate layer 140 may be electrically connected to a third gate layer 160 in the second-type thin film transistor TFT2.

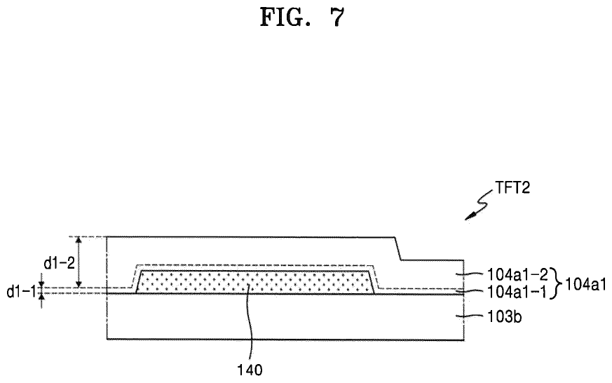

FIGS. 7 to 10 are cross-sectional views schematically illustrating a process of manufacturing the second-type thin film transistor of FIG. 5 or 6. For reference, redundant descriptions of FIGS. 7 to 10 with the above descriptions may be omitted for conciseness.

For convenience of description, some components may not be illustrated in FIGS. 7 to 10, and those of ordinary skill in the art may clearly infer the components not illustrated in FIGS. 7 to 10 from FIG. 5 or 6 and may also clearly infer the manufacturing process and manufacturing sequence of the components not illustrated in FIGS. 7 to 10 from FIG. 5 or 6.

As illustrated in FIGS. 7 to 10, a second gate layer 140 may be formed over a second gate insulating layer 103b (e.g., directly on an upper surface thereof). A first interlayer insulating layer 104a may be formed over (e.g., directly thereon) the second gate layer 140 and the second gate insulating layer 103b. In an embodiment, the first interlayer insulating layer 104a may be an inorganic protection layer and may include a groove pattern CP that is downwardly concave. The groove pattern CP may be referred to as a “concave pattern”. For example, the groove pattern CP may have a downwardly concave shape (e.g., in a cross-sectional view). For example, a second semiconductor layer 150 may be arranged over (e.g., directly thereon) the groove pattern CP, and the groove pattern CP may correspond to a pattern of the second semiconductor layer 150.

In an embodiment, the first interlayer insulating layer 104a may include a first inorganic protection layer 104a1. The first inorganic protection layer 104a1 may include a first-1 inorganic protection layer 104a1-1 and a first-2 inorganic protection layer 104a1-2. The first-1 inorganic protection layer 104a1-1 may be arranged over (e.g., disposed directly thereon) the second gate layer 140 and may cover the upper surface and the side surfaces of the second gate layer 140. The first-2 inorganic protection layer 104a1-2 may be arranged over (e.g., disposed directly thereon) the first-1 inorganic protection layer 104a1-1.

In an embodiment, the first inorganic protection layer 104a1 may be a multilayer including the first-1 inorganic protection layer 104a1-1 including SiNₓ and the first-2 inorganic protection layer 104a1-2 including SiOₓ. Since the first inorganic protection layer 104a1 is a multilayer, penetration of impurities into the second semiconductor layer 150 may be effectively prevented.

For example, the first-1 inorganic protection layer 104a1-1 may be arranged over (e.g., disposed directly thereon) the second gate layer 140. The first-1 inorganic protection layer 104a1-1 may have a first-1 thickness d1-1 (e.g., length in the vertical direction). In an embodiment, the first-1 inorganic protection layer 104a1-1 may include SiNₓ.

For example, the first-2 inorganic protection layer 104a1-2 may be arranged over (e.g., disposed directly thereon) the first-1 inorganic protection layer 104a1-1. The first-2 inorganic protection layer 104a1-2 may have a first-2 thickness d1-2 (e.g., length in the vertical direction). In an embodiment, the first-2 inorganic protection layer 104a1-2 may include SiOₓ.

In an embodiment in which the first-1 inorganic protection layer 104a1-1 includes SiNₓ, it may perform a barrier function for effectively preventing penetration of impurities (e.g., F) into the second semiconductor layer 150 due to the excellent layer properties of SiNₓ. As a result, since impurities do not penetrate into the second semiconductor layer 150, the characteristics of the first thin film transistor T1 including the second semiconductor layer 150 may be increased.

In an embodiment in which the first-2 inorganic protection layer 104a1-2 includes SiOₓ, the possibility of existence of extra oxygen atoms may increase. Due to the extra oxygen atoms (exO) generated in the first-2 inorganic protection layer 104a1-2, the first-2 inorganic protection layer 104a1-2 may perform a barrier function for effectively preventing penetration of impurities (e.g., F) into the second semiconductor layer 150 during a high-temperature thermal process. As a result, because impurities do not penetrate into the second semiconductor layer 150, the characteristics of the first thin film transistor T1 including the second semiconductor layer 150 may be increased.

Also, since the first inorganic protection layer 104a1 has a bilayer structure including the first-1 inorganic protection layer 104a1-1 and the first-2 inorganic protection layer 104a1-2, the first inorganic protection layer 104a1 may perform a barrier function for preventing penetration of impurities (e.g., F) into the second semiconductor layer 150 during a high-temperature thermal process.

The first-1 thickness d1-1 may be less than the first-2 thickness d1-2. For example, in an embodiment the first-1 thickness d1-1 may be in a range of about 300 angstroms to about 1,000 angstroms. For example, the first-1 thickness d1-1 may be about 500 angstroms.

The first-2 thickness d1-2 may be greater than the first-1 thickness d1-1. For example, in an embodiment the first-2 thickness d1-2 may be about 2,000 angstroms to about 4,000 angstroms. For example, the first-2 thickness d1-2 may be about 3,000 angstroms.

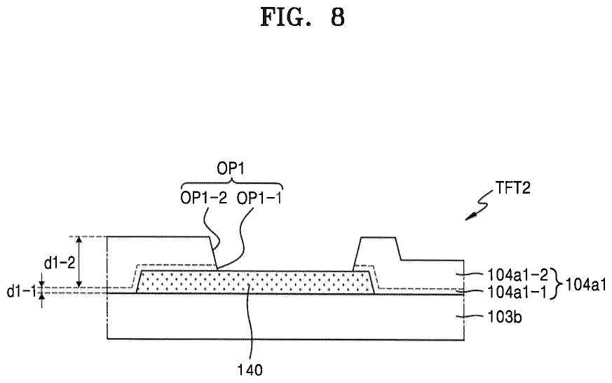

As illustrated in FIG. 8, an opening OP1 upwardly exposing at least a portion of the upper surface of the second gate layer 140 may be formed in the first inorganic protection layer 104a1. For example, a first-1 opening OP1-1 upwardly exposing at least a portion of the upper surface of the second gate layer 140 may be formed in the first-1 inorganic protection layer 104a1-1, and a first-2 opening OP1-2 having an inner surface continuous with and aligned with the inner surface of the first-1 opening OP1-1 may be formed in the first-2 inorganic protection layer 104a1-2. In an embodiment, the first-1 opening OP1-1 and the first-2 opening OP1-2 may be formed in the same process. The inner surface of each of the first-1 opening OP1-1 and the first-2 opening OP1-2 may include an inclined surface, and the inner surface of each of the first-1 opening OP1-1 and the first-2 opening OP1-2 may form a continuous aligned surface.

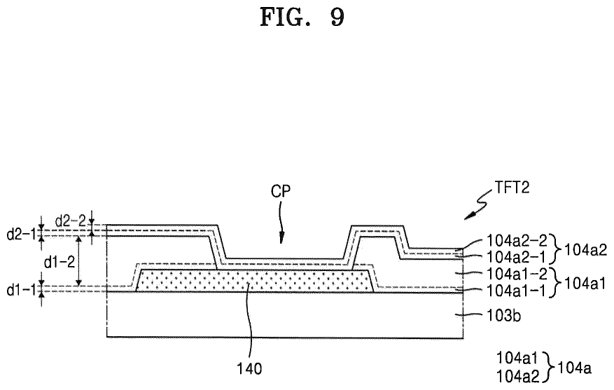

As illustrated in FIG. 9, in an embodiment the first interlayer insulating layer 104a may further include a second inorganic protection layer 104a2. The second inorganic protection layer 104a2 may be formed over (e.g., disposed directly thereon) the first inorganic protection layer 104a1.

The second inorganic protection layer 104a2 may cover a portion of the upper surface of the second gate layer 140 upwardly exposed by the first-1 opening OP1-1. The second inorganic protection layer 104a2 may cover the inner surface of the first-1 opening OP1-1 and the inner surface of the first-2 opening OP1-2. The second inorganic protection layer 104a2 may cover the upper surface of the first inorganic protection layer 104a1. The second inorganic protection layer 104a2 may be arranged over (e.g., directly thereon) the first-2 inorganic protection layer 104a1-2 and may cover the upper surface of the first-2 inorganic protection layer 104a1-2.

In an embodiment, the second inorganic protection layer 104a2 may include a second-1 inorganic protection layer 104a2-1 and a second-2 inorganic protection layer 104a2-2. The second-1 inorganic protection layer 104a2-1 may be arranged over (e.g., disposed directly thereon) the first-2 inorganic protection layer 104a1-2, and the second-2 inorganic protection layer 104a2-2 may be arranged over (e.g., disposed directly thereon) the second-1 inorganic protection layer 104a2-1.

In an embodiment, the second inorganic protection layer 104a2 may be a multilayer including the second-1 inorganic protection layer 104a2-1 including SiNₓ and the second-2 inorganic protection layer 104a2-2 including SiOₓ. Since the second inorganic protection layer 104a2 is a multilayer, penetration of impurities into the second semiconductor layer 150 may be effectively prevented.

For example, the second-1 inorganic protection layer 104a2-1 may have a second-1 thickness d2-1. The second-1 inorganic protection layer 104a2-1 may include SiNₓ. For example, the second-2 inorganic protection layer 104a2-2 may have a second-2 thickness d2-2. The second-2 inorganic protection layer 104a2-2 may include SiOₓ.

The second-1 thickness d2-1 may be less than or equal to the second-2 thickness d2-2. For example, in an embodiment the second-1 thickness d2-1 may be in a range of about 200 angstroms to about 600 angstroms. For example, in an embodiment the second-2 thickness d2-2 may be in a range of about 500 angstroms to about 700 angstroms. For example, in an embodiment in which the second-1 thickness d2-1 is 500 angstroms, the second-2 thickness d2-2 may be 500 angstroms. For example, in an embodiment in which the second-1 thickness d2-1 may be 250 angstroms, the second-2 thickness d2-2 may be 500 angstroms. The thickness of the portion of the first interlayer insulating layer 104a between (e.g., directly therebetween) the second gate layer 140 and the second semiconductor layer 150, such as the total thickness of the second inorganic protection layer 104a2 (e.g., the sum of d2-1 and d2-2) may be less than the total thickness of remaining portions of the first interlayer insulating layer 104a which are not disposed between (e.g., directly therebetween) the second gate layer 140 and the second semiconductor layer 150.

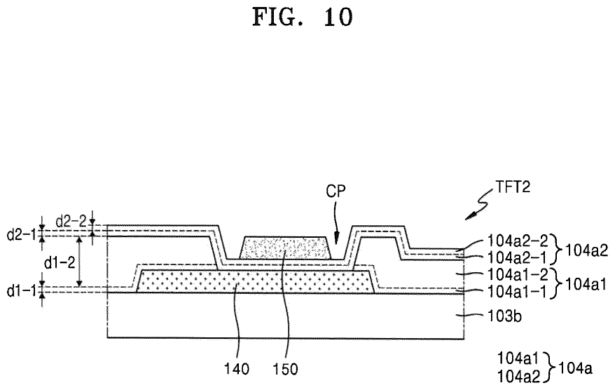

As illustrated in FIG. 10, a second semiconductor layer 150 may be formed over (e.g., directly thereon) the second inorganic protection layer 104a2. The second semiconductor layer 150 may be arranged in the groove pattern CP formed by the first inorganic protection layer 104a1 and the second inorganic protection layer 104a2. The groove pattern CP may have a concave shape corresponding to the shape of the second semiconductor layer 150. The groove pattern CP may be formed in the respective layers (104a1-1, 104a1-2, 104a2-1, and 104a2-2) of the first inorganic protection layer 104a1 and the second inorganic protection layer 104a2, which may provide a structure for accommodating the second semiconductor layer 150. In an embodiment, the second semiconductor layer 150 may include an oxide semiconductor, which may function as a channel area of the second-type thin film transistor TFT2.

The thickness (e.g., the sum of d2-1 and d2-2) of the second inorganic protection layer 104a2 may be less than the thickness (e.g., the sum of d1-1 and d1-2) of the first inorganic protection layer 104a1. The respective thicknesses of the first and second inorganic protection layers 104a1, 104a2 may help to optimize the arrangement of the second semiconductor layer 150 by adjusting the depth of the groove pattern CP.

This structure may increase the electrical characteristics of the second-type thin film transistor TFT2 by stably arranging the second semiconductor layer 150 in the groove pattern CP. In an embodiment, by the groove pattern CP, the second semiconductor layer 150 may be arranged farther from layers including a conductive material, such as the third gate layer 160 arranged around the second-type thin film transistor TFT2. As the distance between the second semiconductor layer 150 and the conductive material such as the third gate layer 160 arranged around the second-type thin film transistor TFT2 increases, the parasitic capacitance between the two components may be prevented or reduced. As the parasitic capacitance is prevented or reduced, the electrical characteristics of the second-type thin film transistor TFT2 may be increased.

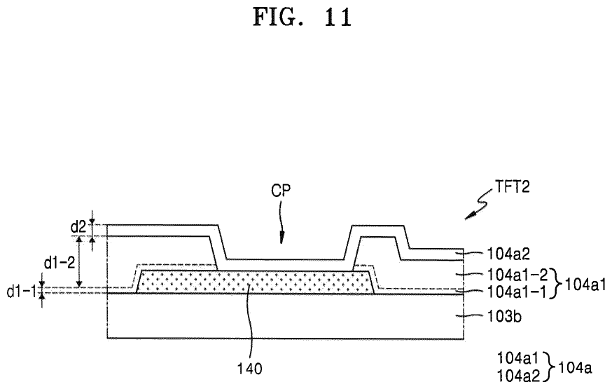

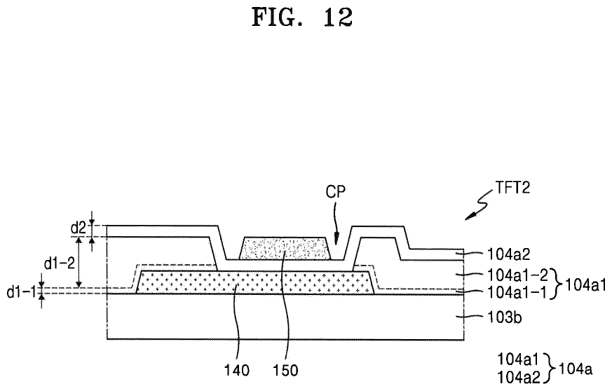

FIGS. 11 and 12 are cross-sectional views schematically illustrating a common process of manufacturing a portion of the second-type thin film transistor of FIG. 5 or 6. For reference, redundant descriptions of FIGS. 11 and 12 with the above descriptions may be omitted for conciseness.

For convenience of description, some components may not be illustrated in FIGS. 11 and 12, and those of ordinary skill in the art may clearly infer the components not illustrated in FIGS. 11 and 12 from FIG. 5 or 6 and may also clearly infer the manufacturing process and manufacturing sequence of the components not illustrated in FIGS. 11 and 12 from FIG. 5 or 6.

As illustrated in FIG. 11, in an embodiment a second inorganic protection layer 104a2 may be formed as a single layer. Unlike the second inorganic protection layer 104a2 in an embodiment shown in FIG. 9, the second inorganic protection layer 104a2 of FIG. 11 may include only a single layer.

For example, the second inorganic protection layer 104a2 may include SiNₓ or SiOₓ. For example, the second inorganic protection layer 104a2 may be a single layer including SiNₓ or may be a single layer including SiOₓ. A process of forming the second inorganic protection layer 104a2 of FIG. 11 may be simpler and less expensive than a process of forming the second inorganic protection layer 104a2 of FIG. 9.

For example, a second thickness d2 of the second inorganic protection layer 104a2 may be greater than the first-1 thickness d1-1 of the first-1 inorganic protection layer 104a1-1. For example, the second thickness d2 of the second inorganic protection layer 104a2 may be less than the first-2 thickness d1-2 of the first-2 inorganic protection layer 104a1-2. Thus, the second thickness d2 may be greater than the first-1 thickness d1-1 and less than the first-2 thickness d1-2.

As illustrated in FIG. 12, a second semiconductor layer 150 may be formed over (e.g., directly thereon) the second inorganic protection layer 104a2. The second semiconductor layer 150 may be arranged in a groove pattern CP formed in the first inorganic protection layer 104a1 and the second inorganic protection layer 104a2. In an embodiment, the groove pattern CP may have a concave shape corresponding to the shape of the second semiconductor layer 150. The groove pattern CP may be formed in the first inorganic protection layer 104a1 and the second inorganic protection layer 104a2, which may provide a structure for accommodating the second semiconductor layer 150. The second semiconductor layer 150 may include an oxide semiconductor, which may function as a channel area of the second-type thin film transistor TFT2.

The second thickness d2 of the second inorganic protection layer 104a2 may be less than the thickness (e.g., the sum of d1-1 and d1-2) of the first inorganic protection layer 104a1. The respective thicknesses of the first and second inorganic protection layers 104a1, 104a2 may help to optimize the arrangement of the second semiconductor layer 150 by adjusting the depth of the groove pattern CP.

This structure may increase the electrical characteristics of the second-type thin film transistor TFT2 by stably arranging the second semiconductor layer 150 in the groove pattern CP. In an embodiment, due to the groove pattern CP, the second semiconductor layer 150 may be arranged farther from layers including a conductive material, such as the third gate layer 160 arranged around the second-type thin film transistor TFT2. As the distance between the second semiconductor layer 150 and the conductive material such as the third gate layer 160 arranged around the second-type thin film transistor TFT2 increases, the parasitic capacitance between the two components may be prevented or reduced. As the parasitic capacitance is prevented or reduced, the electrical characteristics of the second-type thin film transistor TFT2 may be increased.

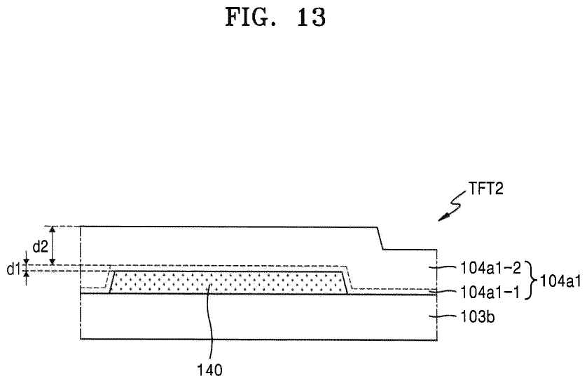

FIGS. 13 to 15 are cross-sectional views schematically illustrating a common process of manufacturing the second-type thin film transistor of FIG. 5 or 6. For reference, redundant descriptions of FIGS. 13 to 15 with the above descriptions may be omitted for conciseness.

For convenience of description, some components may not be illustrated in FIGS. 13 to 15, and those of ordinary skill in the art may clearly infer the components not illustrated in FIGS. 13 to 15 from FIG. 5 or 6 and may also clearly infer the manufacturing process and manufacturing sequence of the components not illustrated in FIGS. 13 to 15 from FIG. 5 or 6.

As illustrated in FIG. 13, in an embodiment the second-type thin film transistor TFT2 may not include a second inorganic protection layer 104a2. In an embodiment, a first inorganic protection layer 104a1 may include a first-1 inorganic protection layer 104a1-1 and a first-2 inorganic protection layer 104a1-2. In an embodiment, the first-1 inorganic protection layer 104a1-1 may include SiNₓ as described above, and the first-2 inorganic protection layer 104a1-2 may include SiOₓ as described above.

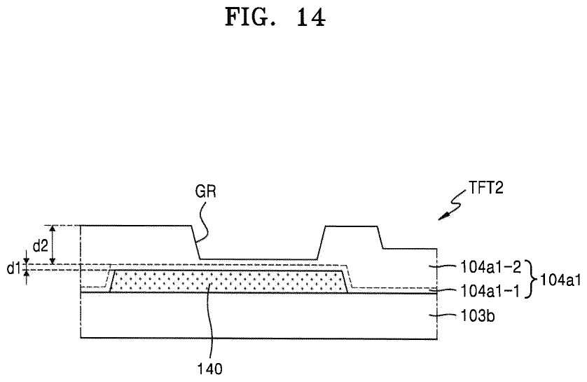

As illustrated in FIG. 14, a groove GR may be formed in the first-2 inorganic protection layer 104a1-2. The groove GR may be formed in the first-2 inorganic protection layer 104a1-2, which may provide a structure for accommodating the second semiconductor layer 150. The groove GR formed in the first-2 inorganic protection layer 104a1-2 may have a concave shape corresponding to the shape of the second semiconductor layer 150.

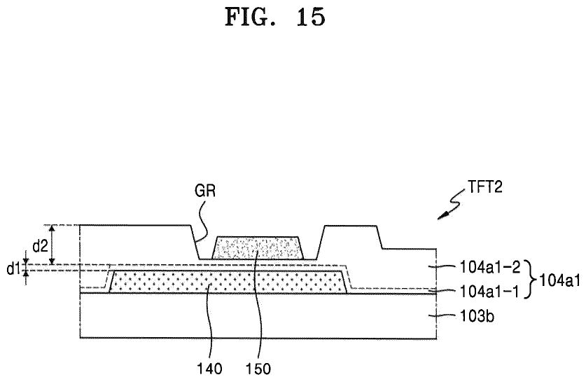

As illustrated in FIG. 15, a second semiconductor layer 150 may be formed over (e.g., directly thereon) the first-2 inorganic protection layer 104a1-2. The second semiconductor layer 150 may be arranged in the groove GR formed in the first-2 inorganic protection layer 104a1-2. The groove GR formed in the first-2 inorganic protection layer 104a1-2 may have a concave shape corresponding to the shape of the second semiconductor layer 150.

The thickness of the first-1 inorganic protection layer 104a1-1 may be less than the thickness of the first-2 inorganic protection layer 104a1-2. The respective thickness of the first-1 and first-2 inorganic protection layers 104a1-1, 104a1-2 may help to optimize the arrangement of the second semiconductor layer 150 by adjusting the depth of the groove GR formed in the first-2 inorganic protection layer 104a1-2. The thickness of the portion of the first interlayer insulating layer 104a between (e.g., directly therebetween) the second gate layer 140 and the second semiconductor layer 150, such as the total thickness of the first inorganic protection layer 104a1 may be less than the thickness of remaining portions of the first interlayer insulating layer 104a which are not disposed between (e.g., directly therebetween) the second gate layer 140 and the second semiconductor layer 150.

This structure may increase the electrical characteristics of the second-type thin film transistor TFT2 by stably arranging the second semiconductor layer 150 in the groove GR. In an embodiment, due to the groove GR, the second semiconductor layer 150 may be arranged farther from layers including a conductive material, such as the third gate layer 160 arranged around the second-type thin film transistor TFT2. As the distance between the second semiconductor layer 150 and the conductive material such as the third gate layer 160 arranged around the second-type thin film transistor TFT2 increases, the parasitic capacitance between the two components may be prevented or reduced. As the parasitic capacitance is prevented or reduced, the electrical characteristics of the second-type thin film transistor TFT2 may be increased.

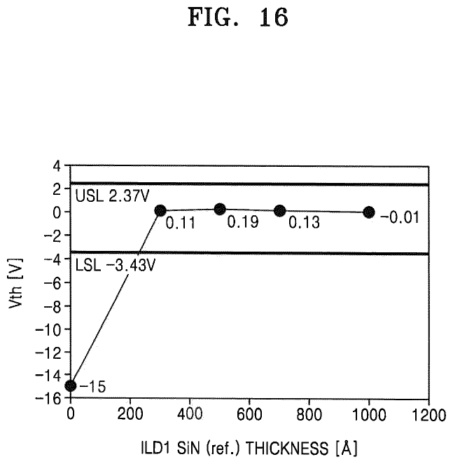

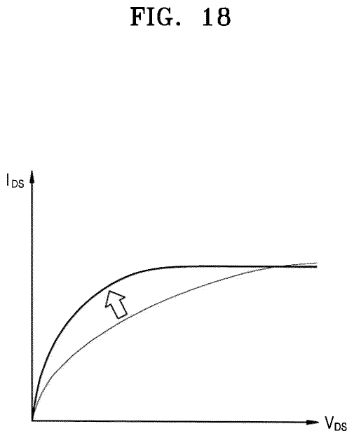

FIG. 16 is a graph illustrating the measurement of a change in the threshold voltage of the first thin film transistor depending on a change in the thickness of the first-1 inorganic protection layer of FIGS. 7 to 10, FIG. 17 is a graph illustrating a subthreshold slope (SS) of the first thin film transistor depending on a change in the parasitic capacitance described above, and FIG. 18 is a graph illustrating a change in the I-V curve of the first thin film transistor depending on a change in the SS.

Referring to FIG. 16, the threshold voltage of the first thin film transistor T1 should satisfy a range of about −3.43 V to about 2.37 V (hereinafter referred to as an optimal range). The first-1 inorganic protection layer 104a1-1 may be a layer including SiNₓ. It is seen that the threshold voltage of the first thin film transistor T1 is 0.11 V within the optimal range when the thickness of the first-1 inorganic protection layer 104a1-1 is 300 angstroms. Even when the thickness of the first-1 inorganic protection layer 104a1-1 increases to 1,000 angstroms, the threshold voltage of the first thin film transistor T1 is within the optimal range.

The thickness of the first-1 inorganic protection layer 104a1-1 may be 300 angstroms or more. When the thickness of the first-1 inorganic protection layer 104a1-1 is 300 angstroms or more, the threshold voltage of the first thin film transistor T1 may be within the optimal range and the electrical characteristics of the first thin film transistor T1 may also be increased.

In an embodiment, the thickness of the first-1 inorganic protection layer 104a1-1 may be in a range of about 300 angstroms to about 1,000 angstroms. When the thickness of the first-1 inorganic protection layer 104a1-1 is about 300 angstroms to about 1,000 angstroms, the threshold voltage of the first thin film transistor T1 may be within the optimal range and the electrical characteristics of the first thin film transistor T1 may also be increased.

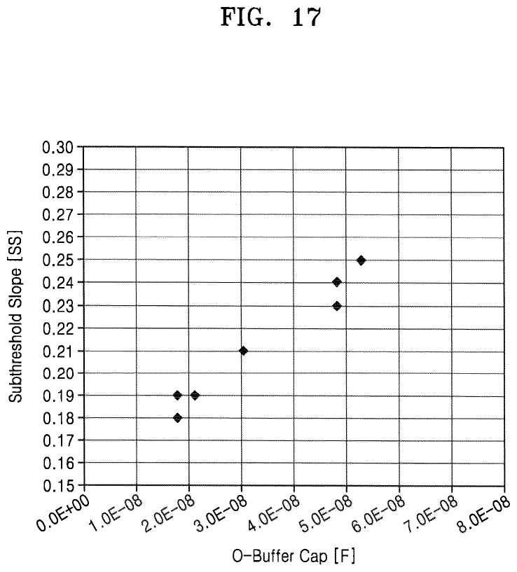

Referring to FIG. 17, the x-axis of the graph represents the size of the parasitic capacitance that decreases as the thickness of the first-2 inorganic protection layer 104a1-2 decreases. The parasitic capacitance may be a capacitance generated by a line layer (e.g., the third gate layer 160) including a conductive material arranged between the second-type thin film transistor TFT2 and the second semiconductor layer 150 of the second-type thin film transistor TFT2.

As shown in FIG. 17 the SS of the first thin film transistor T1 also decreases as the parasitic capacitance decreases. Thus, it may be interpreted that the parasitic capacitance decreases as the thickness of the first-2 inorganic protection layer 104a1-2 decreases and the characteristics of the first thin film transistor T1 are increased by the decreased parasitic capacitance.

Referring to FIG. 18, as the SS of FIG. 17 increases, the I-V curve of the first thin film transistor T1 may move along an arrow. As the I-V curve moves upward, the operation characteristics of the first thin film transistor T1 depending on the threshold voltage may be increased.

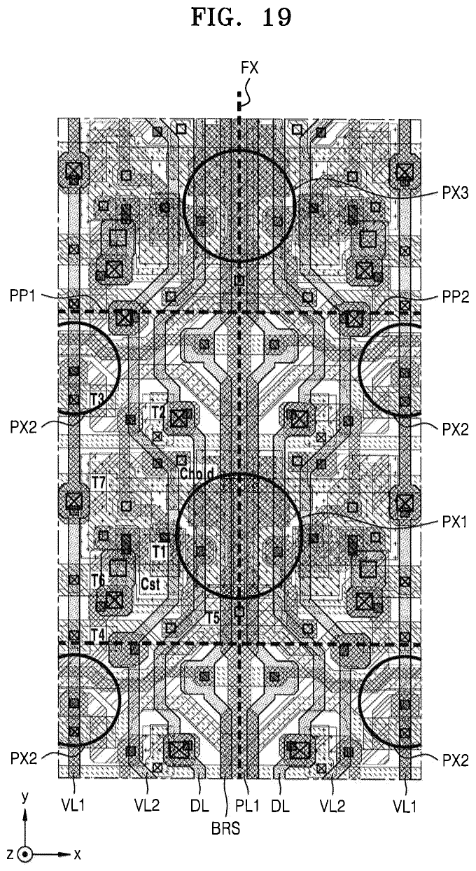

FIG. 19 is a plan view schematically illustrating a layout of a portion of the display area of FIG. 1. For convenience of description, redundant descriptions of components may be omitted for conciseness. For reference, the layout of FIGS. 19 to 29 may be understood based on the equivalent circuit diagram of FIG. 4.

As illustrated in FIG. 19, components may be arranged symmetrically with respect to a virtual center line FX. Components arranged on one side of the virtual center line FX and components arranged on the other side of the virtual center line FX may be symmetrical with respect to the virtual center line FX.

A first pixel area PX1 to a third pixel area PX3 may be a pixel area defined by the pixel definition layer 108 and may refer to an area that emits light corresponding to each pixel area to the outside of the display apparatus (e.g., the external environment). For example, the first pixel area PX1 and the third pixel area PX3 may be arranged to overlap the virtual center line FX, and the second pixel area PX2 may be a plurality of pixel areas and may be arranged to not overlap the virtual center line FX and be laterally symmetrical with respect to the virtual center line FX.

For example, in an embodiment the first pixel area PX1 may be an area that emits red visible light in the visible light range, the second pixel area PX2 may be an area that emits green visible light in the visible light range, and the third pixel area PX3 may be an area that emits blue visible light in the visible light range. However, embodiments of the present disclosure are not necessarily limited thereto.

The first thin film transistor T1 may be arranged around the first pixel area PX1. The first thin film transistor T1 may overlap the storage capacitor Cst in the plan view. The second thin film transistor T2 may be arranged over and/or under the first thin film transistor T1 and/or the storage capacitor Cst in the plan view.

In the plan view, the hold capacitor Chold may be arranged between the first thin film transistor T1 and the second thin film transistor T2. In the plan view, the hold capacitor Chold may not overlap the second thin film transistor T2.

The storage capacitor Cst may be arranged between the first thin film transistor T1, the fourth thin film transistor T4, the fifth thin film transistor T5, and the sixth thin film transistor T6 in the plan view.

The power line PL1 may extend along the virtual center line FX or in the y-axis direction. The power line PL1 may overlap the first pixel area PX1 in the plan view. The power line PL1 may overlap the third pixel area PX3 in the plan view.

The data line DL may be arranged around the virtual center line FX and may extend in the y-axis direction. The data line DL may overlap the hold capacitor Chold in the plan view. The data line DL may overlap the second thin film transistor T2 in the plan view. The data line DL may overlap the fifth thin film transistor T5 in the plan view.

The reference voltage line VL1 may extend in the y-axis direction and may overlap the second pixel area PX2 in the plan view. The initialization voltage line VL2 may overlap the storage capacitor Cst and the first thin film transistor T1 in the plan view. The initialization voltage line VL2 may overlap the hold capacitor Chold in the plan view.

A first pixel circuit area PP1 and a second pixel circuit area PP2 may be defined around the first thin film transistor T1. The virtual center line FX may be arranged between the first pixel circuit area PP1 and the second pixel circuit area PP2. Hereinafter, descriptions of the plan view illustrating the layout will focus on the components arranged in the first pixel circuit area PP1, and descriptions of the components arranged in the second pixel circuit area PP2 and other areas may be omitted for economy of description. For example, the components arranged in the second pixel circuit area PP2 may be arranged symmetrically with respect to the components arranged in the first pixel circuit area PP1 with respect to the virtual center line FX.

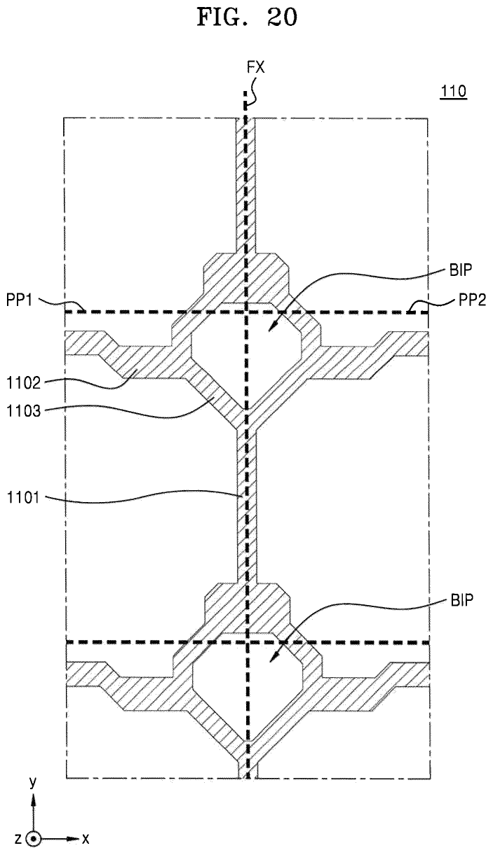

FIGS. 20 to 29 are plan views schematically illustrating the layouts illustrated in FIG. 19 in the stacking order thereof.

As illustrated in FIG. 20, the lower metal layer 110 may be arranged over the substrate 100 (see FIG. 5 or 6). For example, the lower metal layer 110 may be arranged between the upper surface of the substrate 100 and the first semiconductor layer 120 of the first-type thin film transistor TFT1.

In an embodiment, the lower metal layer 110 may include a first portion 1101 to a third portion 1103. The first portion 1101 of the lower metal layer 110 may extend in the y-axis direction and overlap the virtual center line FX in the plan view. The second portion 1102 of the lower metal layer 110 may extend substantially in the x-axis direction and may be connected to the third portion 1103 of the lower metal layer 110. A portion of the third portion 1103 of the lower metal layer 110 may extend in a diagonal direction between the x-axis direction and the y-axis direction and be directly connected to the first portion 1101 and the second portion 1102. An opening area BIP may be formed in the third portion 1103 of the lower metal layer 110. The opening area BIP may be defined by a border area of the third portion 1103 of the lower metal layer 110. For example, in an embodiment the opening area BIP of the third portion 1103 of the lower metal layer 110 may have a polygonal shape in the plan view. However, embodiments of the present disclosure are not necessarily limited thereto.

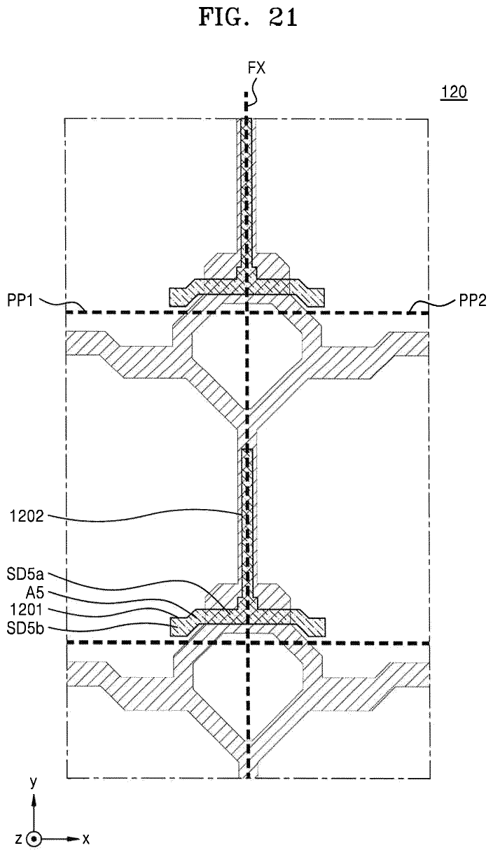

As illustrated in FIG. 21, the first semiconductor layer 120 may be arranged over the lower metal layer 110. For example, the first semiconductor layer 120 may be arranged between the lower metal layer 110 and the first gate layer 130 (e.g., in a vertical direction).

In an embodiment, the first semiconductor layer 120 may include a first portion 1201 and a second portion 1202. The first portion 1201 of the first semiconductor layer 120 may extend substantially in the x-axis direction. For example, the first portion 1201 of the first semiconductor layer 120 may include a channel area A5 and source-drain areas SD5a and SD5b of the fifth thin film transistor T5. The channel area A5 of the fifth thin film transistor T5 may be arranged between the source-drain areas SD5a and SD5b of the fifth thin film transistor T5. A first source-drain area SD5a among the source-drain areas SD5a and SD5b may be arranged around a central area of the first portion 1201 of the first semiconductor layer 120, and a second source-drain area SD5b among the source-drain areas SD5a and SD5b may be arranged at or around one end (e.g., lateral ends) of the first portion 1201.

The second portion 1202 of the first semiconductor layer 120 may extend substantially in the y-axis direction, and the second portion 1202 of the first semiconductor layer 120 may overlap the virtual center line FX in the plan view. The second portion 1202 of the first semiconductor layer 120 may be connected to (e.g., directly connected thereto) the central area of the first portion 1201 of the first semiconductor layer 120. The second portion 1202 of the first semiconductor layer 120 may overlap the first portion 1101 of the lower metal layer 110 in the plan view.

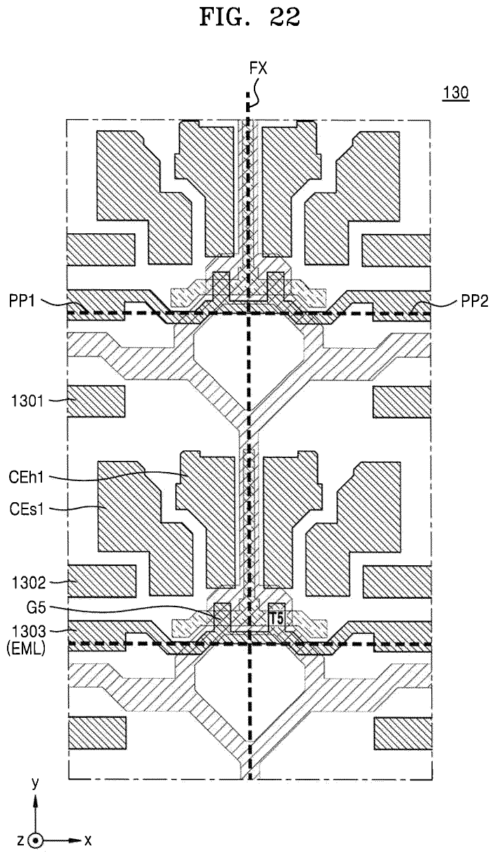

As illustrated in FIG. 22, the first gate layer 130 may be arranged over the first semiconductor layer 120. For example, the first gate layer 130 may be arranged between the first semiconductor layer 120 and the second gate layer 140 (e.g., in the vertical direction). In an embodiment, the first gate layer 130 may include a first electrode CEs1 among the electrodes of the storage capacitor Cst. The first gate layer 130 may include a first electrode CEh1 among the electrodes of the hold capacitor Chold. For example, the first electrode CEs1 of the storage capacitor Cst and the first electrode CEh1 of the hold capacitor Chold may be spaced apart from each other in the plan view.

The first electrode CEs1 of the storage capacitor Cst may be spaced apart from a portion of a third portion 1301 of the first gate layer 130 (e.g., a gate electrode G5 of the fifth thin film transistor T5) in the y-axis direction in the plan view. The first electrode CEs1 of the storage capacitor Cst may have a particular width, and the first electrode CEs1 of the storage capacitor Cst may be spaced apart from the first electrode CEh1 of the hold capacitor Chold in the x-axis direction. The first electrode CEh1 of the hold capacitor Chold may have a particular width, and the first electrode CEh1 of the hold capacitor Chold may be spaced apart from the first electrode CEs1 of the storage capacitor Cst in the-x-axis direction. For example, in an embodiment each of the first electrode CEs1 of the storage capacitor Cst and the first electrode CEh1 of the hold capacitor Chold may have an isolated shape.

The first gate layer 130 may further include a first portion 1301 to a third portion 1303. The first portion 1301 and the second portion 1302 of the first gate layer 130 may extend substantially in the x-axis direction, and the first electrode CEs1 of the storage capacitor Cst may be arranged between the first portion 1301 and the second portion 1302 of the first gate layer 130 in the plan view (e.g., in the y-axis direction).

The third portion 1303 of the first gate layer 130 may extend substantially in the x-axis direction. In an embodiment, the third portion 1303 of the first gate layer 130 may be a line for transmitting a scan signal applied to the fifth thin film transistor T5. For example, a portion of the third portion 1303 of the first gate layer 130 may protrude in the y-axis direction in the plan view.

For example, a portion of the third portion 1303 of the first gate layer 130 may be a gate electrode G5 of the fifth thin film transistor T5. For example, a portion of the third portion 1303 of the first gate layer 130 may overlap the first portion 1101 of the lower metal layer 110 in the plan view. For example, a portion of the third portion 1303 of the first gate layer 130 may overlap a channel area A5 of the first portion 1101 of the lower metal layer 110 in the plan view.

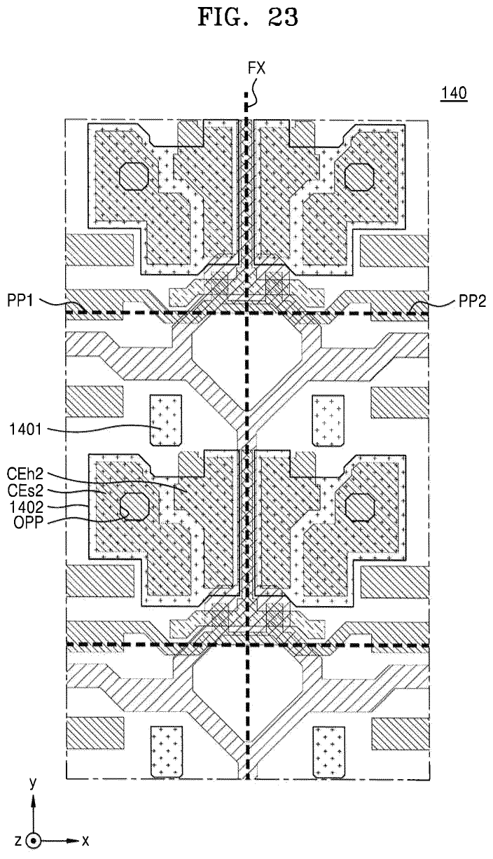

As illustrated in FIG. 23, the second gate layer 140 may be arranged over the first gate layer 130. In an embodiment, the second gate layer 140 may include a second electrode CEs2 among the electrodes of the storage capacitor Cst and a second electrode CEh2 among the electrodes of the hold capacitor Chold. In the plan view, the second gate layer 140 may not overlap the lower metal layer 110.

The second gate layer 140 may include a first portion 1401 not overlapping the lower metal layer 110, the first semiconductor layer 120, and the first gate layer 130 in the plan view, and a second portion 1402 overlapping the first electrodes CEs1 and CEh1 included in the first gate layer 130 in the plan view. In an embodiment, the second portion 1402 of the second gate layer 140 may be integrally formed.

In an embodiment, a portion of the second portion 1402 of the second gate layer 140 that overlaps the first electrode CEs1 of the storage capacitor Cst in the plan view may be the second electrode CEs2 of the storage capacitor Cst. A portion of the second portion 1402 of the second gate layer 140 that overlaps the first electrode CEh1 of the hold capacitor Chold in the plan view may be the second electrode CEh2 of the hold capacitor Chold.

An opening portion OPP may be formed in a central area of the second electrode CEh2 of the hold capacitor Chold in the second portion 1402 of the second gate layer 140. Through the opening portion OPP, the first electrode CEh1 of the hold capacitor Chold and the component (e.g., a portion of the first conductive layer SD1) over the second gate layer 140 may be electrically connected to each other.

In an embodiment, the shape of the second electrode CEh2 of the hold capacitor Chold may substantially correspond to the shape of the first electrode CEh1 of the hold capacitor Chold. When viewed downward from above (e.g., in plan view) the second gate layer 140, the first electrode CEh1 of the hold capacitor Chold may be completely covered by the second electrode CEh2 of the hold capacitor Chold.

In an embodiment, the shape of the second electrode CEs2 of the storage capacitor Cst may substantially correspond to the shape of the first electrode CEs1 of the storage capacitor Cst. When viewed downward from above the second gate layer 140, the first electrode CEs1 of the storage capacitor Cst may be mostly covered by the second electrode CEs2 of the storage capacitor Cst.

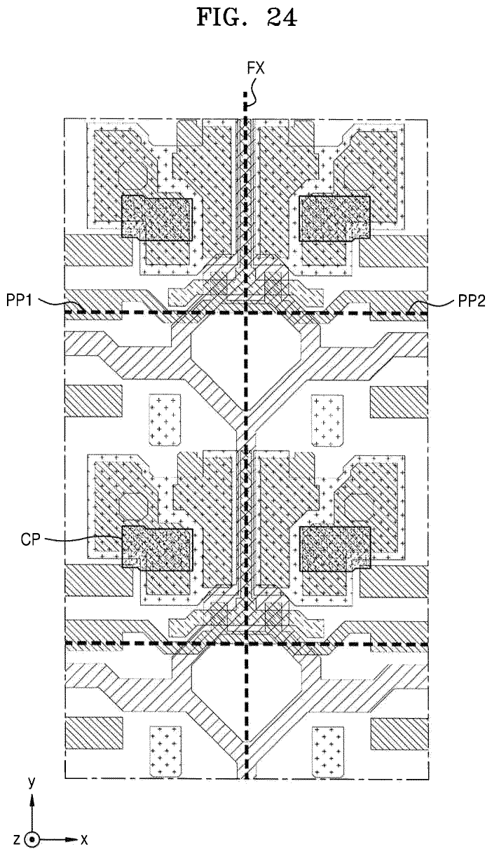

As illustrated in FIG. 24, a groove pattern CP may be formed in the first interlayer insulating layer 104a and the second interlayer insulating layer 104b arranged over the second gate layer 140. Although the transparent first interlayer insulating layer 104a and the second interlayer insulating layer 104b do not appear in a layout image, the groove pattern CP is illustrated in FIG. 24 for convenience of description.

The groove pattern CP may overlap a portion of the second electrode CEh2 of the hold capacitor Chold in the second gate layer 140 in the plan view. The groove pattern CP may overlap a portion of the first electrode CEs1 of the storage capacitor Cst in the first gate layer 130 in the plan view. A portion of the second semiconductor layer 150 described below may be arranged in the groove pattern CP.

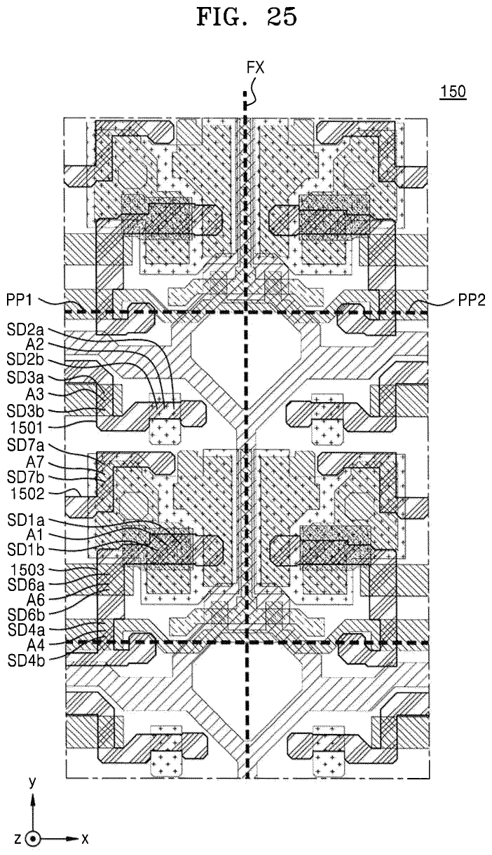

As illustrated in FIG. 25, the second semiconductor layer 150 may be arranged over the second gate layer 140. Also, the second semiconductor layer 150 may be arranged over the first interlayer insulating layer 104a and the second interlayer insulating layer 104b. In an embodiment, the second semiconductor layer 150 may include a first portion 1501, a second portion 1502, and a third portion 1503. In the plan view, the second portion 1502 of the second semiconductor layer 150 may be arranged between the first portion 1501 and the third portion 1503 of the second semiconductor layer 150 (e.g., in the y-axis direction).

The first portion 1501 of the second semiconductor layer 150 may include a channel area A3 and source-drain areas SD3a and SD3b of the third thin film transistor T3. In an embodiment, the channel area A3 and source-drain areas SD3a and SD3b of the third thin film transistor T3 in the first portion 1501 of the second semiconductor 150 may extend in the y-axis direction. The channel area A5 of the third thin film transistor T3 may be arranged between the source-drain areas SD3a and SD3b of the third thin film transistor T3 in the plan view. The channel area A3 of the third thin film transistor T3 may overlap the first portion 1301 of the first gate layer 130 in the plan view.

The first portion 1501 of the second semiconductor layer 150 may include a channel area A2 and source-drain areas SD2a and SD2b of the second thin film transistor T2. In an embodiment, the channel area A2 and source-drain areas SD2a and SD2b of the second thin film transistor T2 in the first portion 1501 of the second semiconductor layer 150 may extend in the x-axis direction. The channel area A2 of the second thin film transistor T2 may be arranged between the source-drain areas SD2a and SD2b of the second thin film transistor T2 in the plan view. The channel area A2 of the second thin film transistor T2 may overlap the first portion 1301 of the first gate layer 130 in the plan view.

The second portion 1502 of the second semiconductor layer 150 may include a channel area A7 and source-drain areas SD7a and SD7b of the seventh thin film transistor T7. In an embodiment, the channel area A7 and source-drain areas SD7a and SD7b of the seventh thin film transistor T7 in the second portion 1502 of the second semiconductor layer 150 may extend in the y-axis direction. The channel area A7 of the seventh thin film transistor T7 may be arranged between the source-drain areas SD7a and SD7b of the seventh thin film transistor T7 in the plan view. The channel area A7 of the seventh thin film transistor T7 may overlap a portion of the first electrode CEh1 of the hold capacitor Chold and a portion of the second electrode CEh2 of the hold capacitor Chold in the plan view.

The third portion 1503 of the second semiconductor layer 150 may include a channel area A1 and source-drain areas SD1a and SD1b of the first thin film transistor T1. In an embodiment, the channel area A1 and source-drain areas SD1a and SD1b of the first thin film transistor T1 in the third portion 1503 of the second semiconductor layer 150 may extend in the x-axis direction. The channel area A1 of the first thin film transistor T1 may be arranged between the source-drain areas SD1a and SD1b of the first thin film transistor T1 in the plan view. The channel area A1 and source-drain areas SD1a and SD1b of the first thin film transistor T1 may overlap the groove pattern CP described above in the plan view. The channel area A1 and source-drain areas SD1a and SD1b of the first thin film transistor T1 may be arranged over the groove pattern CP described above. The channel area A1 and source-drain areas SD1a and SD1b of the first thin film transistor T1 may be arranged in the groove pattern CP described above in the plan view.

The third portion 1503 of the second semiconductor layer 150 may include a channel area A6 and source-drain areas SD6a and SD6b of the sixth thin film transistor T6. In an embodiment, the channel area A6 and source-drain areas SD6a and SD6b of the sixth thin film transistor T6 in the third portion 1503 of the second semiconductor layer 150 may extend in the y-axis direction. The channel area A6 of the sixth thin film transistor T6 may be arranged between the source-drain areas SD6a and SD6b of the sixth thin film transistor T6 in the plan view. The channel area A6 and source-drain areas SD6a and SD6b of the sixth thin film transistor T6 may overlap the second portion 1302 of the first gate layer 130 in the plan view.

The third portion 1503 of the second semiconductor layer 150 may include a channel area A4 and source-drain areas SD4a and SD4b of the fourth thin film transistor T4. In an embodiment, the channel area A4 and source-drain areas SD4a and SD4b of the fourth thin film transistor T4 in the third portion 1503 of the second semiconductor layer 150 may extend in the y-axis direction. The channel area A4 of the fourth thin film transistor T4 may be arranged between the source-drain areas SD4a and SD4b of the fourth thin film transistor T4 in the plan view. The channel area A4 and source-drain areas SD4a and SD4b of the fourth thin film transistor T4 may overlap the third portion 1301 of the first gate layer 130 in the plan view.

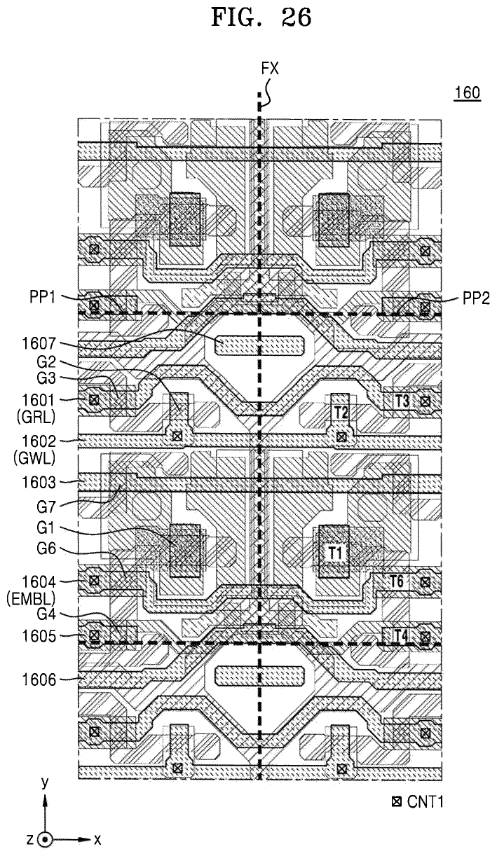

As illustrated in FIG. 26, the third gate layer 160 may be arranged over the second semiconductor layer 150. The third gate layer 160 may be arranged over the second semiconductor layer 150. In an embodiment, the third gate layer 160 may include a first portion 1601 to a seventh portion 1607, and each of the first portion 1601 to the seventh portion 1607 may be separated in the plan view and may have an isolated shape.

The first portion 1601 of the third gate layer 160 may extend substantially in the x-axis direction. The first portion 1601 of the third gate layer 160 may include a gate electrode G3 of the third thin film transistor T3. The gate electrode G3 of the third thin film transistor T3 may overlap the channel area A3 of the third thin film transistor T3 in the second semiconductor layer 150 in the plan view. In an embodiment, the first portion 1601 of the third gate layer 160 may be a scan line GRL for transmitting a scan signal to the gate electrode G3 of the third thin film transistor T3.

For example, in an embodiment the first portion 1601 of the third gate layer 160 may be electrically connected to the first portion 1301 of the first gate layer 130 through a first-type through hole CNT1 downwardly formed.

The second portion 1602 of the third gate layer 160 may extend in the x-axis direction. An area protruding in the y-axis direction in the second portion 1602 of the third gate layer 160 may be a gate electrode G2 of the second thin film transistor T2. Thus, the second portion 1602 of the third gate layer 160 may include the gate electrode G2 of the second thin film transistor T2. The gate electrode G2 of the second thin film transistor T2 may overlap the channel area A2 of the second thin film transistor T2 in the second semiconductor layer 150 in the plan view. In an embodiment, the second portion 1602 of the third gate layer 160 may be a scan line GWL for transmitting a scan signal to the gate electrode G2 of the second thin film transistor T2.

For example, in an embodiment the second portion 1602 of the third gate layer 160 may be electrically connected to the first portion 1401 of the second gate layer 140 through a first-type through hole CNT1 downwardly formed.

The third portion 1603 of the third gate layer 160 may extend in the x-axis direction. A portion of the third portion 1603 of the third gate layer 160 may be a gate electrode G7 of the seventh thin film transistor T7. Thus, the third portion 1603 of the third gate layer 160 may include the gate electrode G7 of the seventh thin film transistor T7. The gate electrode G7 of the seventh thin film transistor T7 may overlap the channel area A7 of the seventh thin film transistor T7 in the second semiconductor layer 150 in the plan view. In an embodiment, the third portion 1603 of the third gate layer 160 may be a scan line for transmitting a scan signal to the gate electrode G7 of the seventh thin film transistor T7.

The fourth portion 1604 of the third gate layer 160 may extend substantially in the x-axis direction. A portion of the fourth portion 1604 of the third gate layer 160 may be a gate electrode G6 of the sixth thin film transistor T6. Thus, the fourth portion 1604 of the third gate layer 160 may include the gate electrode G6 of the sixth thin film transistor T6. The gate electrode G6 of the sixth thin film transistor T6 may overlap the channel area A6 of the sixth thin film transistor T6 in the second semiconductor layer 150 in the plan view. In an embodiment, the fourth portion 1604 of the third gate layer 160 may be a scan line EMBL for transmitting a scan signal to the gate electrode G6 of the sixth thin film transistor T6.

For example, in an embodiment the fourth portion 1604 of the third gate layer 160 may be electrically connected to the second portion 1302 of the first gate layer 130 through a first-type through hole CNT1 downwardly formed.

The fifth portion 1605 of the third gate layer 160 may extend substantially in the x-axis direction. A portion of the fifth portion 1605 of the third gate layer 160 may be a gate electrode G4 of the fourth thin film transistor T4. Thus, the fifth portion 1605 of the third gate layer 160 may include the gate electrode G4 of the fourth thin film transistor T4. The gate electrode G4 of the fourth thin film transistor T4 may overlap the channel area A4 of the fourth thin film transistor T4 in the second semiconductor layer 150 in the plan view. In an embodiment, the fifth portion 1605 of the third gate layer 160 may be a scan line GIL for transmitting a scan signal to the gate electrode G4 of the fourth thin film transistor T4.

For example, in an embodiment the fifth portion 1605 of the third gate layer 160 may be electrically connected to the third portion 1303 of the first gate layer 130 through a first-type through hole CNT1 downwardly formed.

The sixth portion 1606 of the third gate layer 160 may extend substantially in the x-axis direction. In an embodiment, the sixth portion 1606 of the third gate layer 160 may be a line for transmitting a reference voltage Vref or a line for transmitting an initialization voltage Vaint.

The seventh portion 1607 of the third gate layer 160 may be arranged in the opening area BIP of the lower metal layer 110. The seventh portion 1607 of the third gate layer 160 may extend in the x-axis direction and may be arranged in the opening area BIP (FIG. 20) in the plan view. The seventh portion 1607 of the third gate layer 160 may intersect the virtual center line FX in the plan view. The seventh portion 1607 of the third gate layer 160 may be configured to electrically connect a first portion 1701 of the first conductive layer SD1 described below.

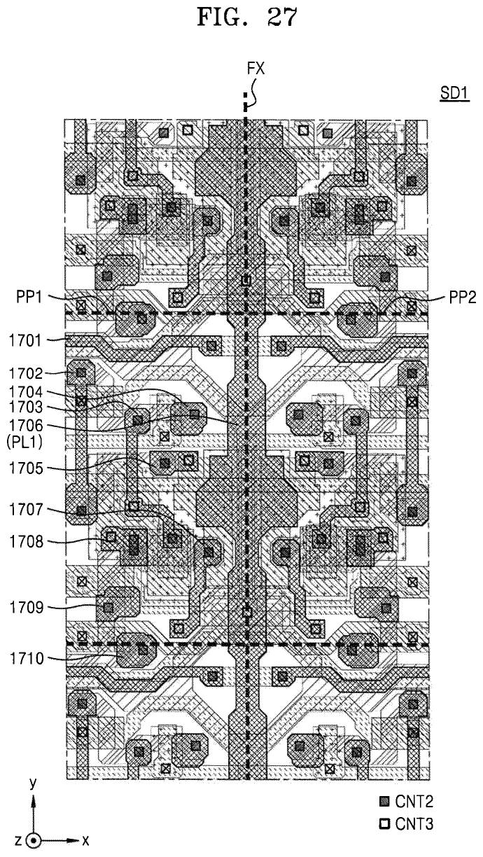

As illustrated in FIG. 27, the first conductive layer SD1 may be arranged over the third gate layer 160. The first conductive layer SD1 may be arranged between the third gate layer 160 and the second conductive layer SD2 (e.g., in the vertical direction). The first conductive layer SD1 may include a first portion 1701 to a tenth portion 1710. In an embodiment, each of the first portion 1701 to the tenth portion 1710 of the first conductive layer SD1 may have an isolated shape in the plan view and may be spaced apart from each other in the plan view.

The first portion 1701 of the first conductive layer SD1 may extend substantially in the x-axis direction. One end of the first portion 1701 of the first conductive layer SD1 may overlap the seventh portion 1607 of the third gate layer 160 described above in the plan view.

For example, in an embodiment one end of the first portion 1701 of the first conductive layer SD1 may be electrically connected to the seventh portion 1607 of the third gate layer 160 through a second-type through hole CNT2 downwardly formed.

The second portion 1702 of the first conductive layer SD1 may extend substantially in the y-axis direction. One end of the second portion 1702 of the first conductive layer SD1 may overlap the first portion 1501 of the second semiconductor layer 150 in the plan view, and the other end of the second portion 1702 of the first conductive layer SD1 may overlap the second portion 1502 of the second semiconductor layer 150 in the plan view.

For example, one end of the second portion 1702 of the first conductive layer SD1 may overlap one area (e.g., SD3a) among the source-drain areas SD3a and SD3b of the third thin film transistor T3 in the plan view. For example, the other end of the second portion 1702 of the first conductive layer SD1 may overlap one area (e.g., SD7b) among the source-drain areas SD7a and SD7b of the seventh thin film transistor T7 in the plan view.

For example, in an embodiment one end of the second portion 1702 of the first conductive layer SD1 may be electrically connected to the first portion 1601 of the second semiconductor layer 150 through a second-type through hole CNT2 downwardly formed. In an embodiment, one end of the second portion 1702 of the first conductive layer SD1 may be electrically connected to one area (e.g., SD3a) among the source-drain areas SD3a and SD3b of the third thin film transistor T3 through a second-type through hole CNT2 downwardly formed.

For example, in an embodiment the other end of the second portion 1702 of the first conductive layer SD1 may be electrically connected to the second portion 1602 of the second semiconductor layer 150 through a second-type through hole CNT2 downwardly formed. In an embodiment, the other end of the second portion 1702 of the first conductive layer SD1 may be electrically connected to one area (e.g., SD7b) among the source-drain areas SD7a and SD7b of the seventh thin film transistor T7 through a second-type through hole CNT2 downwardly formed.

One end of the third portion 1703 of the first conductive layer SD1 may overlap the first portion 1501 of the second semiconductor layer 150 in the plan view, and the other end of the third portion 1703 of the first conductive layer SD1 may overlap the first portion 1601 of the third gate layer 160 in the plan view. For example, one end of the third portion 1703 of the first conductive layer SD1 may overlap one area (e.g., SD2b) among the source-drain areas SD2a and SD2b of the second thin film transistor T2 in the plan view. For example, the other end of the third portion of the first conductive layer SD1 may overlap a gate electrode G1 of the first thin film transistor T1 in the third gate layer 160 in the plan view.

The third portion 1703 of the first conductive layer SD1 may include one portion extending in the y-axis direction and including one end of the third portion 1703 of the first conductive layer SD1, and another portion extending in the x-axis direction and including the other end of the third portion 1703 of the first conductive layer SD1. An area where the one portion and the other portion meet each other may be referred to as a central area of the third portion 1703 of the first conductive layer SD1.

The central area of the third portion 1703 of the first conductive layer SD1 may overlap the first gate layer 130 in the plan view. For example, the central area of the third portion 1703 of the first conductive layer SD1 may overlap the first electrode CEs1 of the storage capacitor Cst in the plan view. For example, the central area of the third portion 1703 of the first conductive layer SD1 may overlap the opening portion OPP of the second electrode CEs2 of the storage capacitor Cst of the first gate layer 130 in the plan view and may be electrically connected to the first electrode CEs1 of the storage capacitor Cst through the opening portion OPP.

For example, one end of the third portion 1703 of the first conductive layer SD1 may be electrically connected to the first portion 1601 of the second semiconductor layer 150 through a second-type through hole CNT2 downwardly formed. In an embodiment, one end of the third portion 1703 of the first conductive layer SD1 may be simultaneously electrically connected to the third thin film transistor T3 and the second thin film transistor T2 through a second-type through hole CNT2 downwardly formed.

For example, the other end of the third portion 1703 of the first conductive layer SD1 may be electrically connected to the third gate layer 160 through a second-type through hole CNT2 downwardly formed. For example, in an embodiment the other end of the third portion 1703 of the first conductive layer SD1 may be electrically connected to the gate electrode G1 of the first thin film transistor T1 through a second-type through hole CNT2 downwardly formed.

For example, the central area of the third portion 1703 of the first conductive layer SD1 may be electrically connected to the first electrode CEs1 of the storage capacitor Cst through a third-type through hole CNT3 downwardly formed.

The fourth portion 1704 of the first conductive layer SD1 may overlap the first portion 1501 of the second semiconductor layer 150 in the plan view. For example, the fourth portion 1704 of the first conductive layer SD1 may overlap one area (e.g., SD2a) among the source-drain areas SD2a and SD2b of the second thin film transistor T2 in the plan view.

The fourth portion 1704 of the first conductive layer SD1 may overlap the first portion 1501 of the second semiconductor layer 150 in the plan view. For example, the fourth portion 1704 of the first conductive layer SD1 may overlap one area (e.g., SD2a) among the source-drain areas SD2a and SD2b of the second thin film transistor T2 in the plan view.

For example, the fourth portion 1704 of the first conductive layer SD1 may be electrically connected to the first portion 1601 of the second semiconductor layer 150 through a second-type through hole CNT2 downwardly formed. In an embodiment, the fourth portion 1704 of the first conductive layer SD1 may be electrically connected to the second thin film transistor T2 through a second-type through hole CNT2 downwardly formed.

The fifth portion 1705 of the first conductive layer SD1 may overlap the second portion 1502 of the second semiconductor layer 150 in the plan view and may simultaneously overlap a portion of the first gate layer 130 in the plan view. For example, one end of the fifth portion 1705 of the first conductive layer SD1 may overlap one area (e.g., SD7a) among the source-drain areas SD7a and SD7b of the seventh thin film transistor T7 in the plan view. For example, the other end of the fifth portion 1705 of the first conductive layer SD1 may overlap the first electrode CEh1 of the hold capacitor Chold in the first gate layer 130 in the plan view.

For example, the fifth portion 1705 of the first conductive layer SD1 may be electrically connected to the second portion 1602 of the second semiconductor layer 150 through a second-type through hole CNT2 downwardly formed. In an embodiment, the fifth portion 1705 of the first conductive layer SD1 may be electrically connected to the seventh thin film transistor T7 through a second-type through hole CNT2 downwardly formed.

The sixth portion 1706 of the first conductive layer SD1 may extend in the y-axis direction. In an embodiment, the sixth portion 1706 of the first conductive layer SD1 may be a power line PL1. The first power voltage ELVDD may be transmitted through the sixth portion 1706 of the first conductive layer SD1. In the plan view, the sixth portion 1706 of the first conductive layer SD1 may overlap the virtual center line FX.

For example, the sixth portion 1706 of the first conductive layer SD1 may be electrically connected to the sixth portion 1606 of the third gate layer 160 through a second-type through hole CNT2 downwardly formed. In an embodiment, the sixth portion 1706 of the first conductive layer SD1 may be electrically connected to a line for transmitting a reference voltage Vref or a line for transmitting an initialization voltage Vaint through a second-type through hole CNT2 downwardly formed.

One end of the seventh portion 1707 of the first conductive layer SD1 may overlap the third portion 1503 of the second semiconductor layer 150 in the plan view, and simultaneously, the other end of the seventh portion 1707 of the first conductive layer SD1 may overlap a portion of the first semiconductor layer 120 in the plan view. For example, one end of the seventh portion 1707 of the first conductive layer SD1 may overlap one area (e.g., SD1a) among the source-drain areas SD1a and SD1b of the first thin film transistor T1 in the plan view. For example, the other end of the seventh portion 1707 of the first conductive layer SD1 may overlap one area (e.g., SD5b) among the source-drain areas SD5a and SD5b of the fifth thin film transistor T5 in the plan view.

For example, one end of the seventh portion 1707 of the first conductive layer SD1 may be electrically connected to the third portion 1503 of the second semiconductor layer 150 through a second-type through hole CNT2 downwardly formed. In an embodiment, one end of the seventh portion 1707 of the first conductive layer SD1 may be electrically connected to the first thin film transistor T1 through a second-type through hole CNT2 downwardly formed.

For example, the other end of the seventh portion 1707 of the first conductive layer SD1 may be electrically connected to the first portion 1501 of the second semiconductor layer 150 through a third-type through hole CNT3 downwardly formed. In an embodiment, the other end of the seventh portion 1707 of the first conductive layer SD1 may be electrically connected to the fifth thin film transistor T5 through a third-type through hole CNT3 downwardly formed.

One end of the eighth portion 1708 of the first conductive layer SD1 may overlap the second electrode CEs2 of the storage capacitor Cst of the second gate layer 140 in the plan view. The other end of the eighth portion 1708 of the first conductive layer SD1 may overlap the groove pattern CP described above in the plan view.

For example, the eighth portion 1708 of the first conductive layer SD1 may be electrically connected to the second portion 1402 of the second gate layer 140 through a third-type through hole CNT3 downwardly formed. In an embodiment, the eighth portion 1708 of the first conductive layer SD1 may be electrically connected to the second electrode CEs2 of the storage capacitor Cst through a third-type through hole CNT3 downwardly formed.

For example, the eighth portion 1708 of the first conductive layer SD1 may be electrically connected to a portion of the second semiconductor layer 150 through a second-type through hole CNT2 downwardly formed. In an embodiment, the eighth portion 1708 of the first conductive layer SD1 may be electrically connected to the first thin film transistor T1 through a second-type through hole CNT2 downwardly formed.

At least a portion of the ninth portion 1709 of the first conductive layer SD1 may overlap the third portion 1503 of the second semiconductor layer 150 in the plan view. For example, at least a portion of the ninth portion 1709 of the first conductive layer SD1 may overlap in an area between one area (e.g., SD6b) among the source-drain areas SD6a and SD6b of the sixth thin film transistor T6 and one area (e.g., SD4a) among the source-drain areas SD4a and SD4b of the fourth thin film transistor T4 in the plan view.

For example, the ninth portion 1709 of the first conductive layer SD1 may be electrically connected to the third portion 1503 of the second semiconductor layer 150 through a second-type through hole CNT2 downwardly formed. In an embodiment, the ninth portion 1709 of the first conductive layer SD1 may be simultaneously electrically connected to the fourth thin film transistor T4 and the sixth thin film transistor T6 through a second-type through hole CNT2 downwardly formed.

For example, the tenth portion 1710 of the first conductive layer SD1 may be electrically connected to the third portion 1503 of the second semiconductor layer 150 through a second-type through hole CNT2 downwardly formed. In an embodiment, the tenth portion 1710 of the first conductive layer SD1 may be electrically connected to the fourth thin film transistor T4 through a second-type through hole CNT2 downwardly formed.

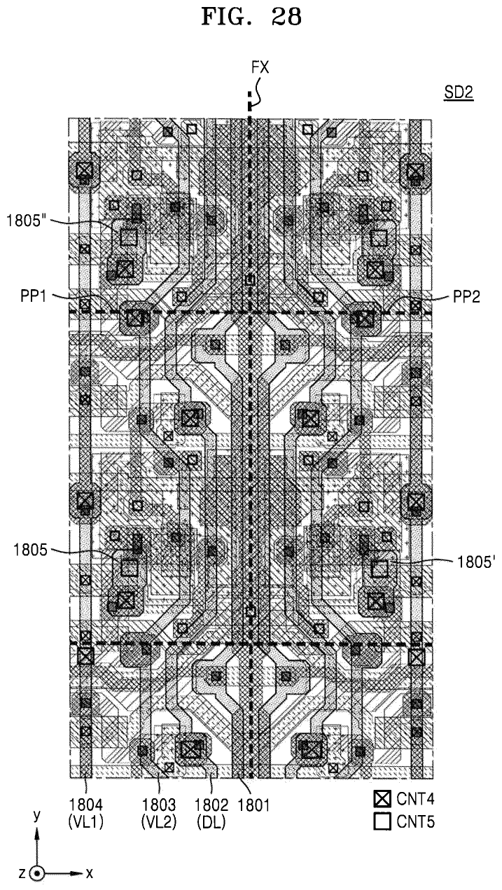

As illustrated in FIG. 28, the second conductive layer SD2 may be arranged over the first conductive layer SD1. The second conductive layer SD2 may be arranged between the first conductive layer SD1 and the pixel electrode layer 170 (e.g., in the vertical direction). In an embodiment, the second conductive layer SD2 may include a first portion 1801 to a fifth portion 1805. In an embodiment, each of the first portion 1801 to the fifth portion 1805 of the second conductive layer SD2 may have an isolated shape in the plan view and may be spaced apart from each other in the plan view.

The first portion 1801 of the second conductive layer SD2 may extend substantially in the y-axis direction. The first portion 1801 of the second conductive layer SD2 may be a connection line BRS. The connection line BRS may partially overlap the sixth portion 1706 of the first conductive layer SD1 in the plan view. In an embodiment, the connection line BRS may partially have a shape corresponding to the shape of the opening area BIP of the lower metal layer 110. In the plan view, the connection line BRS may partially overlap the first electrode CEh1 of the hold capacitor Chold of the first gate layer 130.

In an embodiment, the second portion 1802 of the second conductive layer SD2 may be the data line DL described above. The second portion 1802 of the second conductive layer SD2 may extend substantially in the y-axis direction. The second portion 1802 of the second conductive layer SD2 may overlap the fourth portion 1704 of the first conductive layer SD1 in the plan view.

For example, in an embodiment the second portion 1802 of the second conductive layer SD2 may be electrically connected to the fourth portion 1704 of the first conductive layer SD1 through a fourth-type through hole CNT4 downwardly formed.

For example, the second portion 1802 of the second conductive layer SD2 may be electrically connected to the first portion 1501 of the second semiconductor layer 150 through the fourth portion 1704 of the first conductive layer SD1.

In an embodiment, the third portion 1803 of the second conductive layer SD2 may be the initialization voltage line VL2 described above. The third portion 1803 of the second conductive layer SD2 may extend substantially in the y-axis direction. The third portion 1803 of the second conductive layer SD2 may overlap the tenth portion 1710 of the first conductive layer SD1 in the plan view.

For example, in an embodiment the third portion 1803 of the second conductive layer SD2 may be electrically connected to the tenth portion 1710 of the first conductive layer SD1 through a fourth-type through hole CNT4 downwardly formed.

For example, the third portion 1803 of the second conductive layer SD2 may be electrically connected to the fourth portion 1504 of the second semiconductor layer 150 through the tenth portion 1710 of the first conductive layer SD1. For example, the third portion 1803 of the second conductive layer SD2 may be electrically connected to one area (e.g., SD4b) among the source-drain areas SD4a and SD4b of the fourth thin film transistor T4 through the tenth portion 1710 of the first conductive layer SD1.

In an embodiment, the fourth portion 1804 of the second conductive layer SD2 may be the reference voltage line VL1 described above. The fourth portion 1804 of the second conductive layer SD2 may extend substantially in the y-axis direction. The fourth portion 1804 of the second conductive layer SD2 may overlap the second portion 1702 of the first conductive layer SD1 in the plan view.

For example, the fourth portion 1804 of the second conductive layer SD2 may be electrically connected to the second portion 1702 of the first conductive layer SD1 through a fourth-type through hole CNT4 downwardly formed.

For example, the fourth portion 1804 of the second conductive layer SD2 may be electrically connected to the second portion 1502 of the second semiconductor layer 150 through the other end of the second portion 1702 of the first conductive layer SD1. For example, the fourth portion 1804 of the second conductive layer SD2 may be electrically connected to one area (e.g., SD7b) among the source-drain areas SD7a and SD7b of the seventh thin film transistor T7 through the second portion 1702 of the first conductive layer SD1.

The fifth portion 1805 of the second conductive layer SD2 may be arranged between the third portion 1803 and the fourth portion 1804 of the second conductive layer SD2 in the plan view (e.g., in the x-axis direction). The fifth portion 1805 of the second conductive layer SD2 may overlap the ninth portion 1709 of the first conductive layer SD1 in the plan view.

For example, in an embodiment the fifth portion 1805 of the second conductive layer SD2 may be electrically connected to the ninth portion 1709 of the first conductive layer SD1 through a fourth-type through hole CNT4 downwardly formed.

For example, the fifth portion 1805 of the second conductive layer SD2 may be electrically connected to the third portion 1503 of the second semiconductor layer 150 through the ninth portion 1709 of the first conductive layer SD1. For example, the fifth portion 1805 of the second conductive layer SD2 may be electrically connected to one area (e.g., SD6b) among the source-drain areas SD6a and SD6b of the sixth thin film transistor T6 and one area (e.g., SD4a) among the source-drain areas SD4a and SD4b of the fourth thin film transistor T4 through the ninth portion 1709 of the first conductive layer SD1.

For example, the fifth portion 1805 of the second conductive layer SD2 may be electrically connected to a first pixel electrode 170a of the pixel electrode layer 170 through a fifth-type through hole CNT5 upwardly formed.

For example, in an embodiment a 5′-th portion 1805′ of the second conductive layer SD2 may be electrically connected to a second pixel electrode 170b of the pixel electrode layer 170 through a fifth-type through hole CNT5 upwardly formed.

For example, in an embodiment a 5″-th portion 1805″ of the second conductive layer SD2 may be electrically connected to a third pixel electrode 170c of the pixel electrode layer 170 through a fifth-type through hole CNT5 upwardly formed.

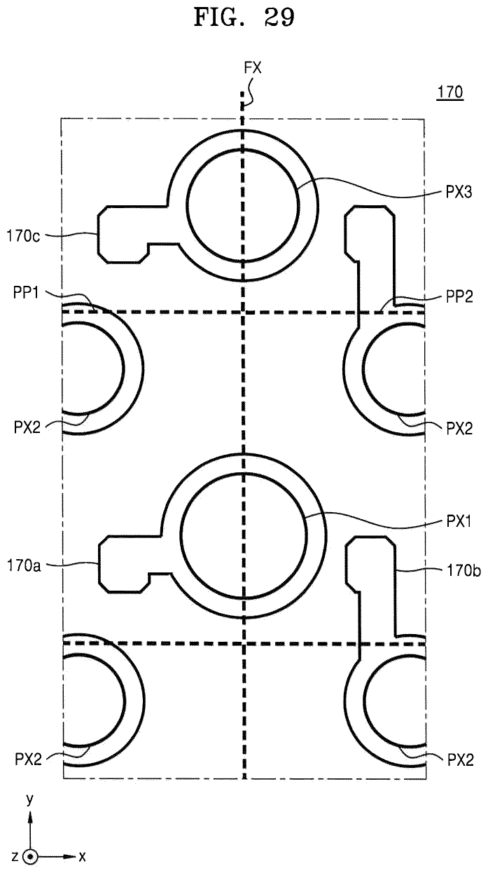

As illustrated in FIG. 29, the pixel electrode layer 170 may be arranged over the second conductive layer SD2. The pixel electrode layer 170 may include a first pixel electrode 170a to a third pixel electrode 170c. In an embodiment, each of the first pixel electrode 170a to the third pixel electrode 170c of the pixel electrode layer 170 may have an isolated shape in the plan view and may be spaced apart from each other in the plan view.

The first pixel electrode 170a of the pixel electrode layer 170 may be a pixel electrode corresponding to the first pixel area PX1. The first pixel area PX1 may be defined by the pixel definition layer 108 covering the edge of the first pixel electrode 170a. The first pixel electrode 170a may overlap the virtual center line FX in the plan view. A portion of the first pixel electrode 170a may protrude in one direction (e.g., in the −x-axis direction), and a portion of the first pixel electrode 170a may overlap the fifth portion 1805 of the second conductive layer SD2 in the plan view.

The second pixel electrode 170b of the pixel electrode layer 170 may be a pixel electrode corresponding to the second pixel area PX2. The second pixel area PX2 may be defined by the pixel definition layer 108 covering the edge of the second pixel electrode 170b. The second pixel electrode 170b may be spaced apart from the first pixel electrode 170a in the plan view. A portion of the second pixel electrode 170b may protrude in one direction (e.g., in the y-axis direction), and a portion of the second pixel electrode 170b may overlap the 5′-th portion 1805′ of the second conductive layer SD2 in the plan view.

The third pixel electrode 170c of the pixel electrode layer 170 may be a pixel electrode corresponding to the third pixel area PX3. The third pixel area PX3 may be defined by the pixel definition layer 108 covering the edge of the third pixel electrode 170c. The third pixel electrode 170c may overlap the virtual center line FX in the plan view. A portion of the third pixel electrode 170c may protrude in one direction (e.g., in the −x-axis direction), and a portion of the third pixel electrode 170c may overlap the 5″-th portion 1805″ of the second conductive layer SD2 in the plan view.

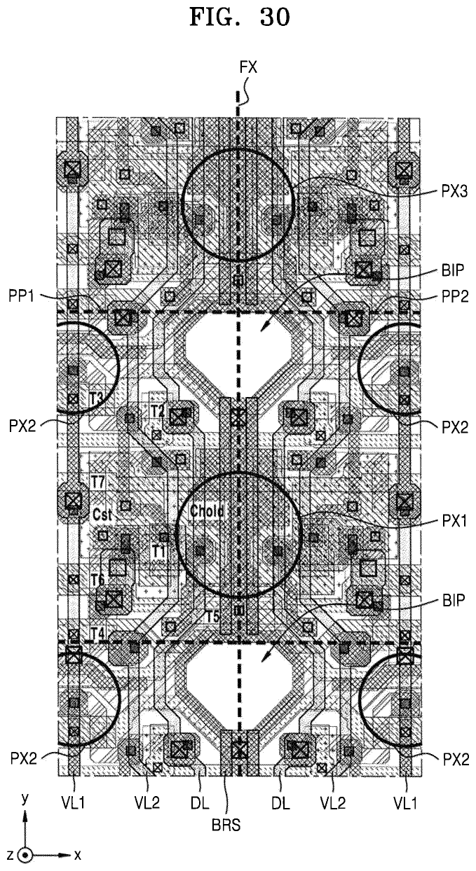

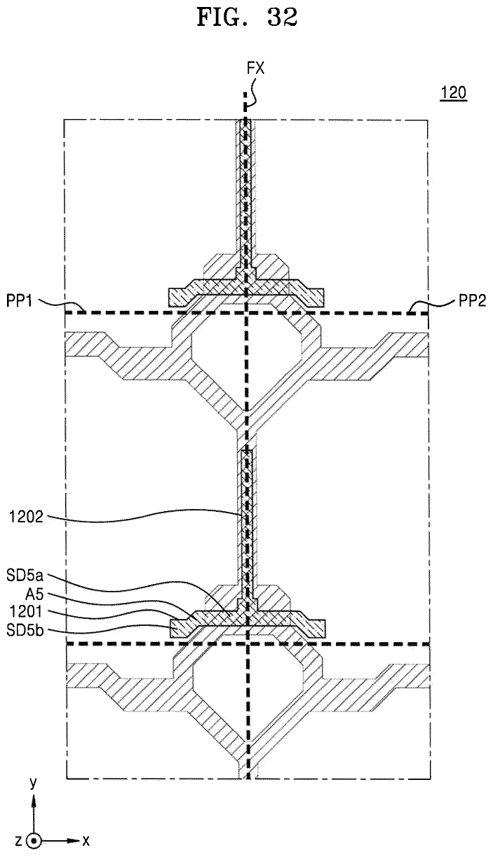

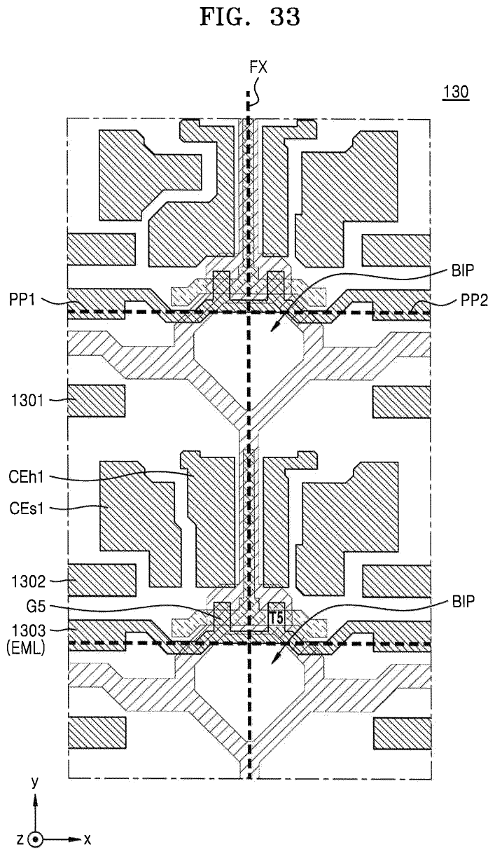

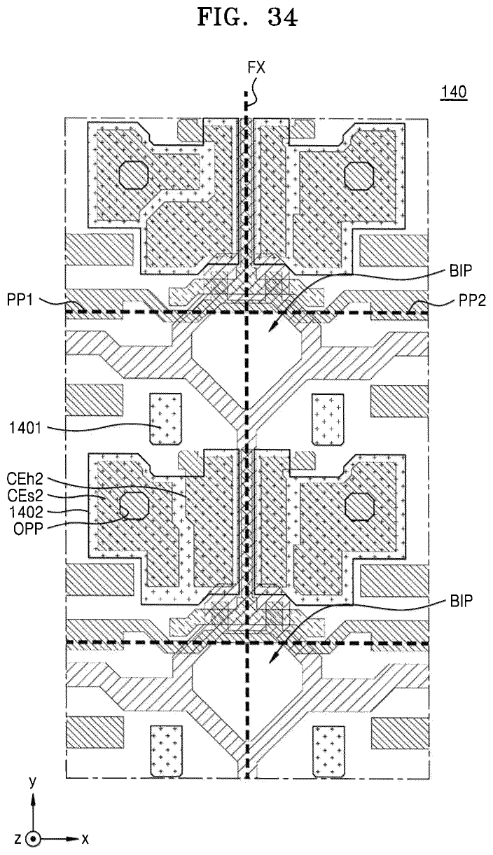

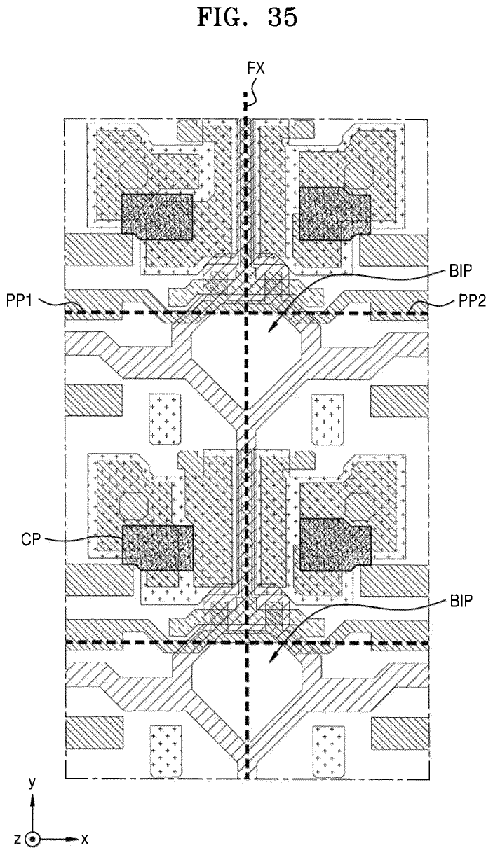

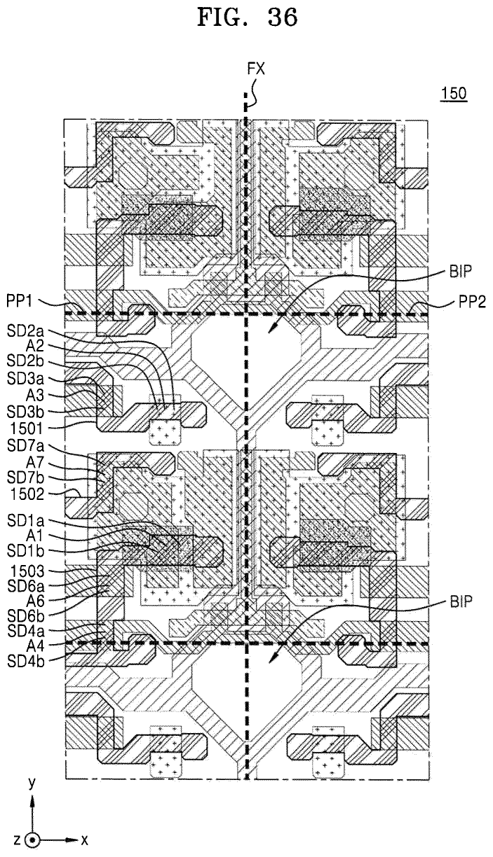

FIG. 30 is a plan view schematically illustrating a layout of a portion of the display area of FIG. 1. For convenience of description, redundant descriptions of components may be omitted for conciseness. For reference, the layout of FIGS. 30 to 39 may be understood based on the equivalent circuit diagram of FIG. 4.

As illustrated in FIG. 30, components may be arranged symmetrically with respect to a virtual center line FX extending in the y-axis direction. Components arranged on one side of the virtual center line FX and components arranged on the other side of the virtual center line FX may be symmetrical with respect to the virtual center line FX.

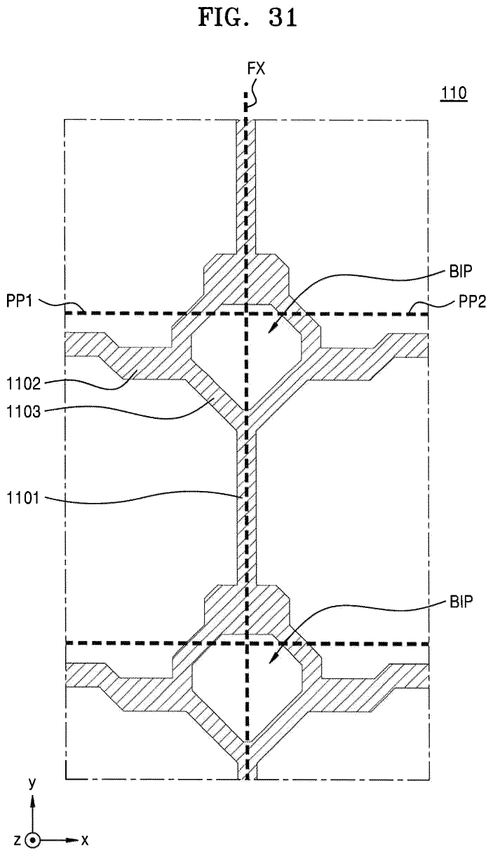

FIGS. 31 to 39 are plan views schematically illustrating the layouts illustrated in FIG. 30 in the stacking order thereof. For reference, descriptions of FIGS. 31 to 36, which are the same drawings as the above drawings, may be omitted for conciseness.

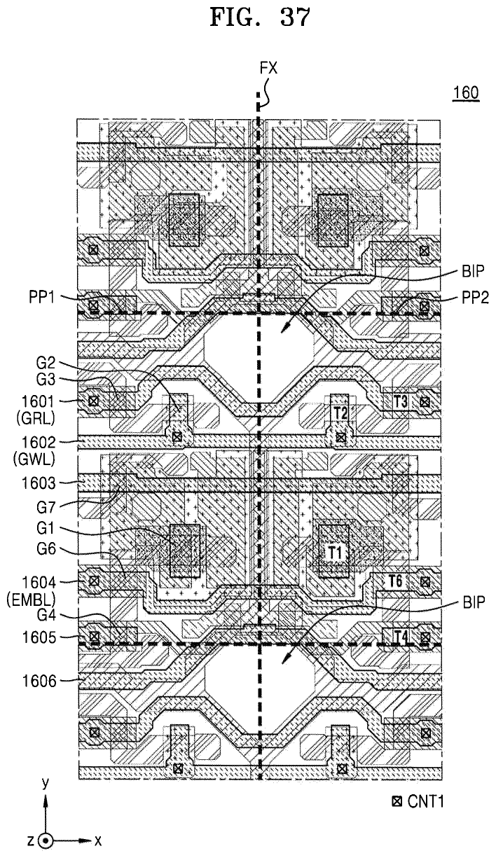

As illustrated in FIG. 37, the first portion 1601 of the third gate layer 160 may extend substantially in the x-axis direction. The first portion 1601 of the third gate layer 160 may not overlap the opening area BIP in the plan view. A portion of the first portion 1601 of the third gate layer 160 may have a shape corresponding to a portion of the third portion 1103 of the lower metal layer 110 defining the opening area BIP.

In an embodiment shown in FIG. 37, the third gate layer 160 may not include the seventh portion 1607 illustrated in FIG. 26. Since the seventh portion 1607 of the third gate layer 160 illustrated in FIG. 26 partially covers the opening area BIP, the seventh portion 1607 of the third gate layer 160 illustrated in FIG. 26 may be omitted to completely open the opening area BIP.

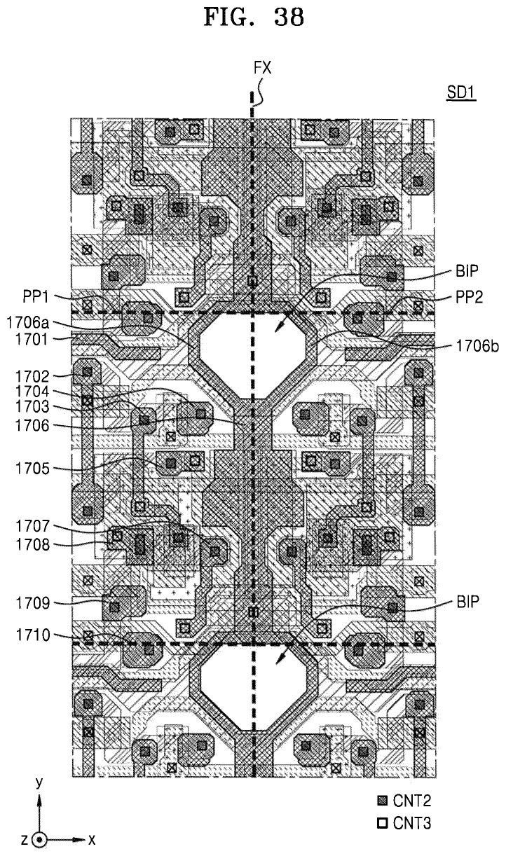

As illustrated in FIG. 38, the first portion 1701 of the first conductive layer SD1 may extend substantially in the x-axis direction. The first portion 1701 of the first conductive layer SD1 of an embodiment shown in FIG. 38 may have a different shape than the first portion 1701 of the first conductive layer SD1 of an embodiment shown in FIG. 27. For example, the first portion 1701 of the first conductive layer SD1 of FIG. 38 may have a smaller length than the first portion 1701 of the first conductive layer SD1 of FIG. 27 so as not to cover the opening area BIP.

The sixth portion 1706 of the first conductive layer SD1 of FIG. 38 may have an opening with a shape corresponding to the opening area BIP. In an embodiment, the sixth portion 1706 of the first conductive layer SD1 of FIG. 38 may include a 6a-th portion 1706a arranged in the first pixel circuit area PP1 and a 6b-th portion 1706b arranged in the second pixel circuit area PP2. The sixth portion 1706 of the first conductive layer SD1 of FIG. 38 may be divided into the 6a-th portion 1706a and the 6b-th portion 1706b and, as a result, may have an opening with a shape corresponding to the opening area BIP.

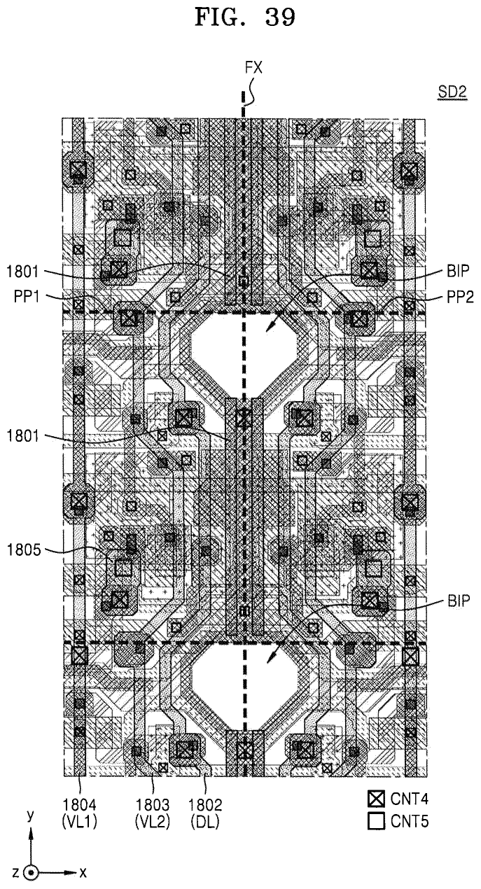

As illustrated in FIG. 39, the first portion 1801 of the second conductive layer SD2 may be disconnected. For example, the first portion 1801 of the second conductive layer SD2 may not cover the opening area BIP. Unlike the first portion 1801 of the second conductive layer SD2 shown in an embodiment of FIG. 12, the first portion 1801 of the second conductive layer SD2 of FIG. 39 may be electrically connected to the sixth portion 1706 of the first conductive layer SD1 located thereunder through a through hole.

For example, in an embodiment the first portion 1801 of the second conductive layer SD2 may be electrically connected to the sixth portion 1706 of the first conductive layer SD1 through a fourth-type through hole CNT4 downwardly formed. In an embodiment, the first portion 1801 of the second conductive layer SD2 may be electrically connected to a power line PL1 for transmitting the first power voltage ELVDD, through a fourth-type through hole CNT4 downwardly formed.

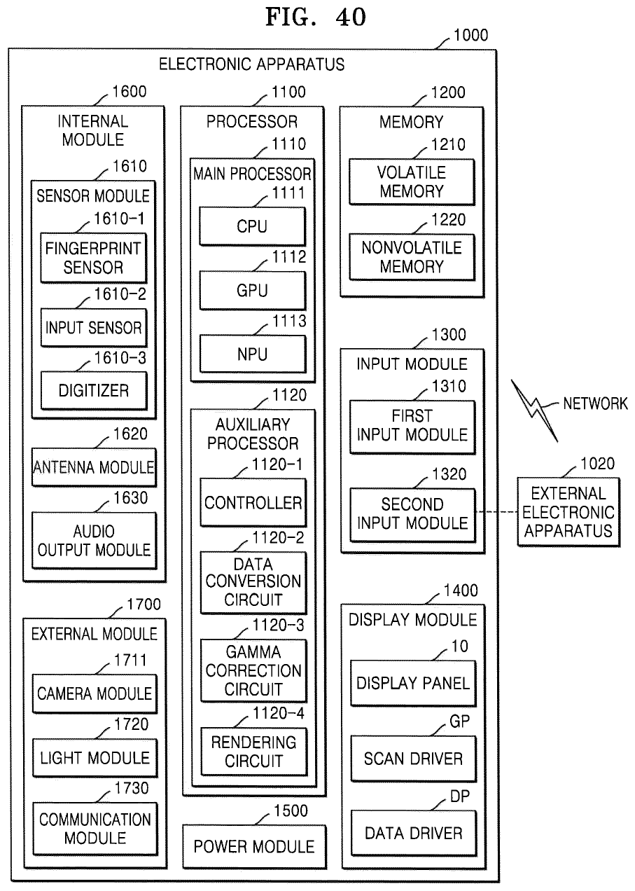

FIG. 40 is a block diagram of an electronic apparatus according to embodiments.

An electronic apparatus 1000 may output various types of information in an operating system through a display module 1400. When a processor 1100 executes an application stored in a memory 1200, the display module 1400 may provide application information to a user through a display panel 10.

The display panel 10 described in FIG. 40 may be understood as the display panel included in one of the display apparatuses of FIGS. 1 to 39.

The processor 1100 may obtain an external input through an input module 1300 or a sensor module 1610 and execute an application corresponding to the external input. For example, when the user selects a camera icon displayed on the display panel 10, the processor 1100 may obtain a user input through an input sensor 1610-2 and activate a camera module 1711. The processor 1100 may transmit, to the display module 1400, image data corresponding to a captured image obtained through the camera module 1711. The display module 1400 may display an image corresponding to the captured image through the display panel 10.

As another example, when personal information authentication is executed in the display module 1400, a fingerprint sensor 1610-1 may obtain input fingerprint information as input data. The processor 1100 may compare the input data obtained through the fingerprint sensor 1610-1 with the authentication data stored in the memory 1200 and execute an application according to the comparison result. The display module 1400 may display, through the display panel 10, information executed according to the logic of the application.

As another example, when a music streaming icon displayed on the display module 1400 is selected, the processor 1100 may obtain a user input through the input sensor 1610-2 and activate a music streaming application stored in the memory 1200. When a music execution command is input in the music streaming application, the processor 1100 may activate an audio output module 1630 to provide the user with audio information corresponding to the music execution command.

The operation of the electronic apparatus 1000 has been briefly described above. Hereinafter, the configuration of the electronic apparatus 1000 will be described in detail. Some of the components of the electronic apparatus 1000 described below may be integrated and provided as one component, and one component may be divided and provided into two or more components.

Referring to FIG. 40, the electronic apparatus 1000 may communicate with an external electronic apparatus 1020 through a network (e.g., a short-range wireless communication network or a long-range wireless communication network). According to an embodiment, the electronic apparatus 1000 may include a processor 1100, a memory 1200, an input module 1300, a display module 1400, a power module 1500, an internal module 1600, and an external module 1700. According to an embodiment, in the electronic apparatus 1000, at least one of the above components may be omitted or one or more other components may be added. According to an embodiment, some (e.g., the sensor module 1610, an antenna module 1620, or the audio output module 1630) of the above components may be integrated into another component (e.g., the display module 1400).

The processor 1100 may execute software to control at least one other component (e.g., a hardware or software component) of the electronic apparatus 1000 connected to the processor 1100 and may perform various data processing or operations. According to an embodiment, as at least a portion of data processing or operation, the processor 1100 may store a command or data received from another component (e.g., the input module 1300, the sensor module 1610, or a communication module 1730) in a volatile memory 1210, process the command or data stored in the volatile memory 1210, and store the resulting data in a nonvolatile memory 1220.

The processor 1100 may include a main processor 1110 and an auxiliary processor 1120. The main processor 1110 may include one or more of a central processing unit (CPU) 1111 and an application processor (AP). The main processor 1110 may further include any one or more of a graphic processing unit (GPU) 1112, a communication processor (CP), and an image signal processor (ISP). The main processor 1110 may further include a neural processing unit (NPU) 1113. The NPU 1113 may be a processor specialized in processing an artificial intelligence model, and the artificial intelligence model may be generated through machine learning. The artificial intelligence model may include a plurality of artificial neural network layers. The artificial neural network may include a deep neural network (DNN), a convolutional neural network (CNN), a recurrent neural network (RNN), a restricted Boltzmann machine (RBM), a deep belief network (DBN), a bidirectional recurrent deep neural network (BRDNN), deep Q-networks, or any combination thereof but is not limited thereto. In addition to a hardware structure, the artificial intelligence model may additionally or alternatively include a software structure. At least two of the processing units and processors described above may be implemented as a single integrated component (e.g., a single chip) or may be respectively implemented as independent components (e.g., a plurality of chips).

The auxiliary processor 1120 may include a controller 1120-1. The controller 1120-1 may include an interface conversion circuit and a timing control circuit. The controller 1120-1 may receive an image signal from the main processor 1110 and convert a data format of the image signal in accordance with the interface specifications with the display module 1400 to output image data. The controller 1120-1 may output various control signals necessary for driving the display module 1400.

The auxiliary processor 1120 may further include a controller 1120-1, a data conversion circuit 1120-2, a gamma correction circuit 1120-3, and a rendering circuit 1120-4. The data conversion circuit 1120-2 may receive image data from the controller 1120-1 and may compensate for the image data such that an image is displayed at a desired brightness according to the characteristics of the electronic apparatus 1000 or the user's settings or may convert the image data for power consumption reduction or afterimage compensation. The gamma correction circuit 1120-3 may convert image data or a gamma reference voltage such that an image displayed on the electronic apparatus 1000 has desired gamma characteristics. The rendering circuit 1120-4 may receive image data from the controller 1120-1 and render the image data in consideration of the pixel arrangement of the display panel 10 applied to the electronic apparatus 1000. At least one of the data conversion circuit 1120-2, the gamma correction circuit 1120-3, and the rendering circuit 1120-4 may be integrated into another component (e.g., the main processor 1110 or the controller 1120-1). At least one of the data conversion circuit 1120-2, the gamma correction circuit 1120-3, and the rendering circuit 1120-4 may be integrated into a data driver DP described below.

The memory 1200 may store various data used by at least one component (e.g., the processor 1100 or the sensor module 1610) of the electronic apparatus 1000 and input data or output data for commands related thereto. The memory 1200 may include at least one of the volatile memory 1210 and the nonvolatile memory 1220.

The input module 1300 may receive a command or data to be used by a component (e.g., the processor 1100, the sensor module 1610, or the audio output module 1630) of the electronic apparatus 1000 from outside the electronic apparatus 1000 (e.g., the user or the external electronic apparatus 1020).

The input module 1300 may include a first input module 1310 into which a command or data is input from the user, and a second input module 1320 into which a command or data is input from the external electronic apparatus 1020. The first input module 1310 may include a microphone, a mouse, a keyboard, a key (e.g., a button), or a pen (e.g., a passive pen or an active pen). The second input module 1320 may support a designated protocol that may be connected to the external electronic apparatus 1020 by wire or wireless. According to an embodiment, the second input module 1320 may include a high-definition multimedia interface (HDMI), a universal serial bus (USB) interface, an SD card interface, or an audio interface. The second input module 1320 may include a connector that may be physically connected to the external electronic apparatus 1020, for example, an HDMI connector, a USB connector, an SD card connector, or an audio connector (e.g., a headphone connector).

The display module 1400 may visually provide information to the user. The display module 1400 may include a display panel 10, a scan driver GP, and a data driver DP. The display module 1400 may further include a window, a chassis, and a bracket for protecting the display panel 10.

The display panel 10 may further include a light emitting driver. The light emitting driver may output an emission control signal to the display panel 10 in response to a control signal received from the controller 1120-1. The light emitting driver may be formed separately from the scan driver GP or may be integrated into the scan driver GP.

The scan driver GP may receive a control signal from the controller 1120-1 and output scan signals to the display panel 10 in response to the control signal. For example, a control signal generated by the controller 1120-1 and transmitted to the scan driver GP may be a scan input signal for controlling the scan driver GP. The scan input signal may be an input signal applied to switching devices included in the stages of the scan driver.

The data driver DP may receive a control signal from the controller 1120-1, convert image data into an analog voltage (e.g., a data voltage) in response to the control signal, and then output data voltages to the display panel 10. For example, the control signal generated by the controller 1120-1 and transmitted to the data driver DP may be a data input signal for controlling the data driver DP.

The data driver DP may be integrated into another component (e.g., the controller 1120-1). The functions of the interface conversion circuit and the timing control circuit of the controller 1120-1 described above may also be integrated into the data driver DP.

The controller 1120-1 may generate a clock signal necessary for driving the scan driver GP. The scan driver GP may generate a scan signal based on a scan input signal, a clock signal, and a scan input voltage. The scan signal may be transmitted to a pixel circuit, and a thin film transistor included in the pixel circuit may be driven based on the scan signal. The scan signal may be transmitted to a gate included in the pixel circuit.

The display module 1400 may further include a light emitting driver and a voltage generation circuit. The voltage generation circuit may output various voltages necessary for driving the display panel 10.

The power module 1500 may supply power to the component of the electronic apparatus 1000. For example, the power module 1500 may generate the first power voltage ELVDD and the second power voltage ELVSS described above. The power module 1500 may generate a gate driving voltage (e.g., Gate High Voltage and Gate Low Voltage) necessary for driving the scan driver GP.

For example, the power module 1500 may refer to a power generation unit, a power supply, or the like. For example, the power module 1500 may include a battery for charging a power voltage. The battery may include a non-rechargeable primary battery, a rechargeable secondary battery, or a fuel cell.

For example, the power module 1500 may include a power management integrated circuit (PMIC). The PMIC may supply optimized power for each of the modules described above and the modules described below.

For example, the power module 1500 may include a wireless power transmission/reception member electrically connected to the battery. The wireless power transmission/reception member may include a plurality of coil-type antenna radiators.

The electronic apparatus 1000 may further include an internal module 1600 and an external module 1700. The internal module 1600 may include a sensor module 1610, an antenna module 1620, and an audio output module 1630. The external module 1700 may include a camera module 1711, a light module 1720, and a communication module 1730.

The sensor module 1610 may sense an input by the user's body or an input by a pen of the first input module 1310 and generate an electric signal or a data value corresponding to the input. The sensor module 1610 may include at least one of a fingerprint sensor 1610-1, an input sensor 1610-2, and a digitizer 1610-3.

The fingerprint sensor 1610-1 may generate a data value corresponding to the user's fingerprint. The fingerprint sensor 1610-1 may include any one of optical or capacitive fingerprint sensors.

The input sensor 1610-2 may generate a data value corresponding to coordinate information of an input by the user's body or an input by the pen. The input sensor 1610-2 may generate a capacitance change due to an input as a data value. The input sensor 1610-2 may sense an input by the passive pen or transmit/receive data to/from the active pen.

The input sensor 1610-2 may also measure a biosignal such as blood pressure, moisture, or body fat. For example, when the user touches a portion of the user's body to a sensor layer or a sensing panel and does not move for a certain time, the input sensor 1610-2 may sense a biosignal based on an electric field change by a portion of the user's body and output information desired by the user to the display module 1400.

The digitizer 1610-3 may generate a data value corresponding to coordinate information of an input by the pen. The digitizer 1610-3 may generate a data value based on an electromagnetic change by the input. The digitizer 1610-3 may sense an input by the passive pen or transmit/receive data to/from the active pen.

At least one of the fingerprint sensor 1610-1, the input sensor 1610-2, and the digitizer 1610-3 may be implemented as a sensor layer formed over the display panel 10 through a continuous process. The fingerprint sensor 1610-1, the input sensor 1610-2, and the digitizer 1610-3 may be arranged on the upper side of the display panel 10, and any one of the fingerprint sensor 1610-1, the input sensor 1610-2, and the digitizer 1610-3, for example, the digitizer 1610-3, may be arranged on the lower side of the display panel 10.

At least two of the fingerprint sensor 1610-1, the input sensor 1610-2, and the digitizer 1610-3 may be formed to be integrated into one sensing panel through the same process. When integrated into one sensing panel, the sensing panel may be arranged between the display panel 10 and the window arranged on the upper side of the display panel 10. According to an embodiment, the sensing panel may be arranged over the window, and the position of the sensing panel is not particularly limited.

At least one of the fingerprint sensor 1610-1, the input sensor 1610-2, and the digitizer 1610-3 may be built in the display panel 10. That is, at least one of the fingerprint sensor 1610-1, the input sensor 1610-2, and the digitizer 1610-3 may be simultaneously formed through a process of forming the devices (e.g., light emitting devices and transistors) included in the display panel 10.

Also, the sensor module 1610 may generate an electric signal or a data value corresponding to an internal state or an external state of the electronic apparatus 1000. The sensor module 1610 may further include, for example, a gesture sensor, a gyro sensor, a pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1620 may include one or more antennas for transmitting/receiving signals or power to/from the outside. According to an embodiment, the communication module 1730 may transmit/receive signals to/from an external electronic apparatus through an antenna suitable for a communication method. An antenna pattern of the antenna module 1620 may be integrated into one component (e.g., the display panel 10) of the display module 1400, the input sensor 1610-2, or the like.

The audio output module 1630 may be a device for outputting audio signals to the outside of the electronic apparatus 1000 and may include, for example, a speaker used for general purposes such as multimedia playback or recording playback and a receiver used exclusively for phone reception. According to an embodiment, the receiver may be formed integrally with or separately from the speaker. An audio output pattern of the audio output module 1630 may be integrated into the display module 1400.

The camera module 1711 may capture still images and moving images. According to an embodiment, the camera module 1711 may include one or more lenses, an image sensor, or an image signal processor. The camera module 1711 may further include an infrared camera that may measure the presence/absence of the user, the user's position, the user's line of sight, and the like.

The light module 1720 may provide light. The light module 1720 may include a light emitting diode or a xenon lamp. The light module 1720 may operate in conjunction with or independently of the camera module 1711.

The communication module 1730 may support establishment of a wired or wireless communication channel between the electronic apparatus 1000 and the external electronic apparatus 1020 and performance of communication through the established communication channel. The communication module 1730 may include any one or all of a wireless communication module such as a cellular communication module, a short-range wireless communication module, or a global navigation satellite system (GNSS) communication module and a wired communication module such as a local area network (LAN) communication module or a power line communication module. The communication module 1730 may communicate with the external electronic apparatus 1020 through a short-range communication network such as Bluetooth, WiFi direct, or Infrared Data Association (IrDA) or a long-range communication network such as a cellular network, the Internet, or a computer network (e.g., LAN or WAN). Various types of communication modules 1730 described above may be implemented as one chip or may be implemented as separate chips.

The input module 1300, the sensor module 1610, and the camera module 1711 may be used to control the operation of the display module 1400 in conjunction with the processor 1100.

The processor 1100 may output a command or data to the display module 1400, the audio output module 1630, the camera module 1711, or the light module 1720 based on the input data received from the input module 1300. For example, the processor 1100 may generate image data corresponding to input data applied through a mouse, an active pen, or the like and output the image data to the display module 1400 or may generate command data corresponding to input data and output the image data to the camera module 1711 or the light module 1720. The processor 1100 may reduce power consumption of the electronic apparatus 1000 by switching the operation mode of the electronic apparatus 1000 to a low-power mode or a sleep mode when no input data is received from the input module 1300 for a certain time.

The processor 1100 may output a command or data to the display module 1400, the audio output module 1630, the camera module 1711, or the light module 1720 based on the sensing data received from the sensor module 1610. For example, the processor 1100 may compare authentication data authorized by the fingerprint sensor 1610-1 with authentication data stored in the memory 1200 and then execute an application according to the comparison result. Based on the sensing data sensed by the input sensor 1610-2 or the digitizer 1610-3, the processor 1100 may execute a command or output corresponding image data to the display module 1400. When the sensor module 1610 includes a temperature sensor, the processor 1100 may receive temperature data about measured temperature from the sensor module 1610 and further perform brightness correction or the like on the image data based on the temperature data.

The processor 1100 may receive measurement data about the presence/absence of the user, the user's position, the user's line of sight, and the like from the camera module 1711. The processor 1100 may further perform brightness correction or the like on the image data based on the measurement data. For example, the processor 1100 that has determined the presence/absence of the user through the input from the camera module 1711 may output image data with brightness corrected through the data conversion circuit 1120-2 or the gamma correction circuit 1120-3 to the display module 1400.

Some of the above components may be connected to each other through a communication method between peripheral devices, such as a bus, a general purpose input/output (GPIO), a serial peripheral interface (SPI), a mobile industry processor interface (MIPI), or an ultra path interconnect (UPI) link to exchange signals (e.g., commands or data) with each other. The processor 1100 may communicate with the display module 1400 through a mutually agreed interface and may use, for example, any one of the above communication methods but is not limited thereto.

The electronic apparatus 1000 according to various embodiments described herein may be various types of devices. The electronic apparatus 1000 may include, for example, at least one of a portable communication device (e.g., a smartphone), a computer device, a portable multimedia device, a portable medical device, a camera, a wearable device, or a home appliance device. The electronic apparatus 1000 according to an embodiment described herein is not limited to the above devices and may be various other small, medium or large-sized electronic devices.

In an embodiment, the electronic apparatus 1000 may include a controller 1120-1, a power module, and a display module. The display module may include a display panel and a scan driver GP. The controller 1120-1 may generate a scan input signal necessary for driving the scan driver GP. Under the control by the processor or the controller 1120-1, the power module may generate a scan input voltage necessary for driving the scan driver GP. For example, the scan input voltage may be a gate driving voltage.

In an embodiment, an electronic apparatus may include a memory storing a command, a processor performing an operation according to the command and generating a control command, and a display panel displaying a screen according to the control command. The display panel may include a substrate, a first semiconductor layer arranged over the substrate, a first gate layer arranged over the first semiconductor layer, a second gate layer arranged over the first gate layer, a first interlayer insulating layer arranged over the second gate layer, a second semiconductor layer arranged over the first interlayer insulating layer and including an oxide semiconductor, a third gate layer arranged over the second semiconductor layer, and a first conductive layer arranged over the third gate layer and electrically connected to the second gate layer. The first interlayer insulating layer may include a groove pattern that is downwardly concave, and a portion of the second semiconductor layer may be arranged in the groove pattern.

In an embodiment, the first interlayer insulating layer may include a first inorganic protection layer including an opening upwardly exposing a portion of an upper surface of the second gate layer, and a second inorganic protection layer arranged over the first inorganic protection layer and covering an inner surface of the opening and a portion of the upper surface of the second gate layer.

In addition, the descriptions of FIGS. 1 to 39 may be applied to the display panel 10 of FIG. 40.

As described above, according to an embodiment, a display apparatus including a thin film transistor with increased electrical characteristics, a method of manufacturing the display apparatus, and an electronic apparatus may be implemented. However, the scope of the present disclosure is not limited to these effects.

It should be understood that embodiments described herein should be considered in a descriptive sense only and not for purposes of limitation. Descriptions of features or aspects within each embodiment should typically be considered as available for other similar features or aspects in other embodiments. While one or more non-limiting embodiments have been described with reference to the figures, it will be understood by those of ordinary skill in the art that various changes in form and details may be made therein without departing from the spirit and scope of the present disclosure.

What is claimed is:

1. A display apparatus comprising:
a substrate;
a first semiconductor layer arranged over the substrate;
a first gate layer arranged over the first semiconductor layer;
a second gate layer arranged over the first gate layer;
a first interlayer insulating layer arranged over the second gate layer, the first interlayer insulating layer including a groove pattern having a downwardly concave shape;
a second semiconductor layer arranged over the first interlayer insulating layer, the second semiconductor layer comprising an oxide semiconductor;
a third gate layer arranged over the second semiconductor layer; and
a first conductive layer arranged over the third gate layer, the first conductive layer is electrically connected to the second gate layer,
wherein, the second semiconductor layer is arranged in the groove pattern.

2. The display apparatus of claim 1, wherein the first interlayer insulating layer comprises:
a first inorganic protection layer including an opening upwardly exposing a portion of an upper surface of the second gate layer; and
a second inorganic protection layer arranged over the first inorganic protection layer, the second inorganic protection layer covering an inner surface of the opening and a portion of the upper surface of the second gate layer.

3. The display apparatus of claim 2, wherein a thickness of the second inorganic protection layer is less than a thickness of the first inorganic protection layer.

4. The display apparatus of claim 2, wherein the first inorganic protection layer comprises:
a first-1 inorganic protection layer having a first-1 thickness, the first-1 inorganic protection layer is disposed directly on the second gate layer; and
a first-2 inorganic protection layer having a first-2 thickness greater than the first-1 thickness, the first-2 inorganic protection layer is disposed directly on the first-1 inorganic protection layer.

5. The display apparatus of claim 2, wherein the first inorganic protection layer comprises:
a first-1 inorganic protection layer comprising silicon nitride (SiNₓ), the first-1 inorganic protection layer is disposed directly on the second gate layer; and
a first-2 inorganic protection layer comprising silicon oxide (SiOₓ), the first-2 inorganic protection layer is disposed directly on the first-1 inorganic protection layer.

6. The display apparatus of claim 4, wherein the second inorganic protection layer comprises a single layer comprising silicon nitride (SiNₓ).

7. The display apparatus of claim 6, wherein a thickness of the second inorganic protection layer is less than or equal to the first-1 thickness.

8. The display apparatus of claim 2, wherein the second inorganic protection layer comprises:
a second-1 inorganic protection layer having a second-1 thickness, the second-1 inorganic protection layer is disposed directly on the first inorganic protection layer; and
a second-2 inorganic protection layer having a second-2 thickness greater than or equal to the second-1 thickness, the second-2 inorganic protection layer is disposed directly on the second-1 inorganic protection layer.

9. The display apparatus of claim 8, wherein the second-2 thickness is less than a thickness of the first inorganic protection layer.

10. The display apparatus of claim 2, wherein the second inorganic protection layer comprises:
a second-1 inorganic protection layer comprising silicon nitride (SiNₓ) and disposed directly on the first inorganic protection layer; and
a second-2 inorganic protection layer including silicon oxide (SiOₓ) and disposed directly on the second-1 inorganic protection layer.

11. The display apparatus of claim 1, wherein a thickness of a portion of the first interlayer insulating layer arranged between the second gate layer and the second semiconductor layer is less than a thickness of a remaining portion of the first interlayer insulating layer.

12. The display apparatus of claim 1, wherein the first conductive layer is electrically connected to the second semiconductor layer.

13. The display apparatus of claim 1, further comprising a pixel electrode arranged over the first conductive layer,
wherein the second semiconductor layer is electrically connected to the pixel electrode.

14. A display apparatus comprising:
a substrate;
a first semiconductor layer arranged over the substrate;
a first gate layer arranged over the first semiconductor layer;
a second gate layer arranged over the first gate layer;
a first interlayer insulating layer arranged over the second gate layer, the first interlayer insulating layer includes a groove pattern having a downwardly concave shape;
a second semiconductor layer arranged over the first interlayer insulating layer, the second semiconductor layer comprising an oxide semiconductor;
a third gate layer arranged over the second semiconductor layer, the third gate layer is electrically connected to the second gate layer; and
a first conductive layer arranged over the third gate layer, the first conductive layer is electrically connected to the second semiconductor layer,
wherein the second semiconductor layer is arranged in the groove pattern.

15. The display apparatus of claim 14, wherein the first interlayer insulating layer comprises:
a first inorganic protection layer including an opening upwardly exposing a portion of an upper surface of the second gate layer; and
a second inorganic protection layer arranged over the first inorganic protection layer, the second inorganic protection layer covering an inner surface of the opening and a portion of the upper surface of the second gate layer.

16. The display apparatus of claim 15, wherein a thickness of the second inorganic protection layer is less than a thickness of the first inorganic protection layer.

17. The display apparatus of claim 15, wherein the first inorganic protection layer comprises:
a first-1 inorganic protection layer having a first-1 thickness, the first-1 inorganic protection layer is disposed directly on the second gate layer; and
a first-2 inorganic protection layer having a first-2 thickness greater than the first-1 thickness, the first-2 inorganic protection layer is disposed directly on the first-1 inorganic protection layer.

18. The display apparatus of claim 15, wherein the first inorganic protection layer comprises:
a first-1 inorganic protection layer comprising silicon nitride (SiNₓ), the first-1 inorganic protection layer is disposed directly on the second gate layer; and
a first-2 inorganic protection layer comprising silicon oxide (SiOₓ), the first-2 inorganic protection layer is disposed directly on the first-1 inorganic protection layer.

19. The display apparatus of claim 14, wherein a thickness of a portion of the first interlayer insulating layer arranged between the second gate layer and the second semiconductor layer is less than a thickness of a remaining portion of the first interlayer insulating layer.

20. An electronic apparatus comprising:
a memory storing a command;
a processor performing an operation according to the command and generating a control command; and
a display panel displaying a screen according to the control command,
wherein the display panel comprises:
a substrate;
a first semiconductor layer arranged over the substrate;
a first gate layer arranged over the first semiconductor layer;
a second gate layer arranged over the first gate layer;
a first interlayer insulating layer arranged over the second gate layer, the first interlayer insulating layer including a groove pattern having a downwardly concave shape;
a second semiconductor layer arranged over the first interlayer insulating layer, the second semiconductor layer comprising an oxide semiconductor;
a third gate layer arranged over the second semiconductor layer; and
a first conductive layer arranged over the third gate layer, the first conductive layer is electrically connected to the second gate layer,
wherein a portion of the second semiconductor layer is arranged in the groove pattern.
